(19) United States
(12) Patent Application Publication
(10) Pub. No.: US 2008/0266042 A1
(43) Pub. Date: Oct. 30, 2008

(54) Transformer unit, and power converting device

(75) Inventors: Hiroyuki Yoshimura, Yokohama City (JP); Masatoshi Sugimoto, Tokyo (JP)

Correspondence Address: RABIN & Berdo, PC, 1101 14TH STREET, NW, SUITE 500, WASHINGTON, DC, 20005, US

(73) Assignee: Fuji Electric Device Technology Co., Ltd, Tokyo (JP)

(21) Appl. No.: 12/078,962

(22) Filed: Apr. 8, 2008

(30) Foreign Application Priority Data
Apr. 27, 2007 (JP) 2007-118188

(51) Int. Cl. H01F 27/34

(52) U.S. Cl. 336/181

(57) ABSTRACT

A transformer unit and a power converting device, which lessen the influence of noise caused by an external magnetic flux, while reducing the temperature dependency of a coupling coefficient, and which transfer signals while insulating a low-voltage and a high-voltage side electrically. Air-core type insulated transformers have a first and second winding of a primary winding as a sending side and a first and second winding of a secondary winding as a receiving side. The windings of the primary winding are connected in parallel and are wound so that the directions of magnetic fields generated by an exciting current oppose each other. The windings of the secondary winding are wound so that electromotive forces to be generated by an external magnetic flux cancel each other, and are connected in series so as to raise the electromotive forces by a signal magnetic flux generated by the primary winding.

### BACKGROUND OF THE INVENTION

1. Field of the Invention

The present invention relates to a transformer unit and a power converting device, and to a method for transmitting signals to switching elements through an air-core type insulated transformer.

2. Description of Related Art

Of recent years, in order to enhance the efficiency of and to reduce the energy consumption of an electric vehicle, a step-up/step-down converter and an inverter are mounted on a drive system for an electric motor to generate driving power. FIG. 19 is a block diagram of a vehicle driving system using a step-up/step-down converter of the related art. In FIG. 19, the vehicle driving system is equipped with: a power source 101 for feeding electric power to a set-up/set-down converter 102; the set-up/set-down converter 102 for setting a voltage up/down; an inverter 103 for converting the voltage outputted from the set-up/set-down converter 102 into a three-phase voltage; and an electric motor 104 for driving the vehicle. Here, the power source 101 can be either a feed voltage from an overhead line or a battery connected in series.

At a vehicle driving time, the set-up/set-down converter 102 sets up the voltage (e.g., 280 V) of the power source 101 to a voltage (e.g., 750 V) suited for driving the electric motor 104, and feeds the set-up voltage to the inverter 103. By ON/OFF control of the switching element, the voltage set up by the set-up/set-down converter 102 is converted into a three-phase voltage so that the speed of the vehicle can be changed by feeding the electric current to the individual phases of the electric motor 104, thereby controlling the switching frequency. At a vehicle braking time, the inverter 103 turns the switching element ON/OFF in synchronism with the voltages rising in the individual phases of the electric motor 104, so that it performs a rectifying action to perform a conversion into a DC voltage, thereby feeding the set-up/set-down converter 102 with the DC voltage. Further, the set-up/set-down converter 102 is enabled to perform the power regenerating actions by dropping the voltage (e.g., 750 V) generated from the electric motor 104 to the voltage (e.g., 280 V) of the power source 101.

FIG. 20 is a block diagram of the step-up/step-down converter of FIG. 19. In FIG. 20, the set-up/set-down converter 102 is equipped with: a reactor L for storing the energy; a capacitor C for storing an electric charge; switching elements SW1 and SW2 for turning the electric current flowing into the inverter 103 ON/OFF; and control circuits 111 and 112 for individually generating control signals to instruct the ON/OFF switching of the switching elements SW1 and SW2.

Further, the switching elements SW1 and SW2 are connected in series, and a node therebetween is connected with the power source 101 through the reactor L. Here, the switching element SW1 is equipped with an IGBT (Insulated Gate Bipolar Transistor) 105 for performing the switching actions in accordance with the control signals from the control circuit 111, and a flywheel diode D1 for feeding the electric current in the direction opposed to that of the electric current flowing to the IGBT 105 is connected in parallel with the IGBT 105. In addition, the switching element SW2 is equipped with an IGBT 106 for performing switching actions in accordance with the control signals from the control circuit 112, and a flywheel diode D2 for feeding the electric current in the direction opposed to that of the electric current flowing to the IGBT 106 is connected in parallel with the IGBT 106. The collector of the IGBT 106 is connected to both the capacitor C and the inverter 103.

FIG. 21 is a diagram showing a waveform of an electric current to flow through the reactor L of FIG. 20 at the set-up operation. In the set-up operation, as shown in FIG. 21, when the IGBT 105 of the switching element SW1 is turned ON (conductive), an electric current I flows through the IGBT 105 to the reactor L so that an energy of LI²/2 is stored in the reactor L. Next, when the IGBT 105 of the switching element SW1 is turned OFF (nonconductive), the electric current flows to the flywheel diode D2 of the switching element SW2, so that the energy stored in the reactor L is fed to the capacitor C. In the set-down action, when the IGBT 106 of the switching element SW2 is turned ON (conductive), the electric current I flows to the reactor L through the IGBT 106, so that the energy of LI²/2 is stored in the reactor L.

Next, when the IGBT 106 of the switching element SW2 is turned OFF (nonconductive), the electric current flows to the flywheel diode D1 of the switching element SW1, so that the energy stored in the reactor L is regenerated to the power source 101. Here, by changing the ON time (ON Duty) of the switching element, the set-up/set-down voltage can be adjusted so that its rough value can be determined from the following Formula (1).

V_{L}/V_{H}=ON Duty (%) (1).

Here, V_{L} indicates the power source voltage, V_{H} indicates the voltage after set-up/set-down, and ON Duty indicates the ratio of a conduction period to the switching period of the switching elements SW1 and SW2.

As a matter of fact, the load and the power source voltage V_{L} fluctuate. Therefore, the voltage V_{H} after set-up/set-down is monitored, so that the ON time (ON Duty) of the switching elements SW1 and SW2 is controlled to set the voltage V_{H} after set-up/set-down may reach the target value. Further, the control circuits 111 and 112 to be earthed to the body casing are on the low-voltage side, and the branch to be connected with the switching elements SW1 and SW2 is on the high-voltage side. In order that the human body may not be exposed to hazards even if difficulties are caused by the failure of the switching elements SW1 and SW2, the signal transfer is made with the branch side by using a signal transmitting insulated transformer to insulate the control circuits 111 and 112 electrically.

FIG. 22 is a top plan view of a signal transmitting insulated transformer of the related art. In FIG. 22, the insulated transformer is equipped with a magnetic core MC, on which a primary winding M1 and a secondary winding M2 are wound. Here, the magnetic core MC can be constituted of a ferromagnetic material such as ferrite or permalloy. Further, the magnetic flux φ, which is generated by an electric current applied to the primary winding M1, is focused by the magnetic core MC, and passes through the magnetic core MC so that it interlinks the secondary winding M2 thereby generating a voltage of dφ/dT at the two ends of the secondary winding M2. Here, a closed magnetic circuit can be formed by using the magnetic core MC, so that the coupling coefficient between the primary winding M1 and the secondary winding M2 can be increased while reducing the influences of the external magnetic field.

FIG. 23 is a block diagram of a signal transmitting circuit using the signal transmitting insulated transformer of the related art. In FIG. 23, an insulated transformer T has its primary winding connected at its one end with the drain of the field effect type transistor M1 through a resistor R1, and has its secondary winding connected at its one end with a demodulating circuit 203. Further, a local oscillation signal, which is generated by a local oscillating circuit 201, is inputted to a modulating circuit 202. When a PWM signal SP is inputted to the modulating circuit 202, the local oscillation signal is modulated by the PWM signal SP, and is inputted as a control signal for the field effect type transistor M1 to the gate of the field effect type transistor M1. When the control signal is inputted to the gate of the field effect type transistor M1, the modulated signal, which is modulated with a high frequency, is transmitted through the insulated transformer T to the modulating circuit 203, in which the PWM signal SP is demodulated.

In Japanese Patent No. 3,399,950 (equivalent to U.S. Pat. No. 5,384,808), there is disclosed a method for transmitting an NRZ data signal through an interface having an isolation barrier arranged between a first device and a second device connected with each other through a bus. The method uses a pulse transformer as the isolation barrier.

However, the method using a transformer with a core as a signal transmitting insulated transformer has problems in that a temperature dependency of a coupling constant is increased by the influence of the temperature characteristics of the permeability of a magnetic member, and that it is difficult to reduce cost and size. Further, the PWM signal itself cannot be directly sent through the transformer with the core so that the modulated signal modulated with the high frequency has to be modulated after being received by the secondary winding. This raises a problem in that the size of the circuit is increased. In a method using an air-core insulated transformer as the signal transmitting insulated transformer, no magnetic core is used, so lower cost and size can be attained. However, the magnetic circuit is not closed so that the external magnetic flux is easily superposed as noise on a secondary winding, thereby causing a risk of inviting a malfunction.

### SUMMARY OF THE INVENTION

Therefore, an object of the invention is to provide a transformer unit and a power converting device, which lessen the influences of noise caused by an external magnetic flux, while reducing the temperature dependency of a coupling coefficient, and which transfer signals while insulating a low-voltage side and a high-voltage side electrically.

In order to solve the aforementioned problems, according to the first aspect of the invention, there is provided a transformer unit comprising a sending-side primary winding, and a receiving-side secondary winding, wherein the sending-side primary winding includes a plurality of windings connected in parallel and set in their individual winding directions so that the directions of magnetic fields to be generated by exciting currents may be contrary to each other, and wherein the receiving-side secondary winding includes a plurality of windings set in their individual winding directions so that electromotive forces to be generated by an external magnetic flux may cancel each other, and connected in series so as to raise the electromotive forces by a signal magnetic flux generated by the primary winding.

As a result, the primary winding and the secondary winding are individually equipped with these windings so that they can cancel the external magnetic fluxes interlinking the primary winding and the secondary winding, thereby reducing the influence of noise, without using any magnetic core, even if the external magnetic fluxes are superposed on the primary winding and the secondary winding. Further, the windings belonging to the primary winding on the sending side are connected in parallel, and the windings belonging to the secondary winding on the receiving side are connected in series, the self-inductance of the secondary winding can be increased while the self-inductance of the primary winding is decreased, so that the received voltage on the secondary winding side can be augmented. As a result, the signal transfer can be made avoiding the risk, as might otherwise invite a malfunction, while insulating the sending side and the receiving side electrically, and the power electronic device can be reduced in cost and size.

In the transformer unit according to the second aspect of the invention, the primary winding includes a first winding and a second winding different from each other in their winding directions such that the leading end of the first winding of the primary winding and the leading end of the second winding of the primary winding are connected with each other, and such that the trailing end of the first winding of the primary winding and the trailing end of the second winding of the primary winding are connected with each other; the secondary winding includes a first winding and a second winding different from each other in their winding directions such that the leading end of the first winding of the secondary winding and the trailing end of the second winding of the secondary winding are connected with each other, or such that the trailing end of the first winding of the secondary winding and the leading end of the second winding of the secondary winding are connected with each other; and the individual first windings and the individual second windings are coaxially arranged whereas the first windings and the second windings of the primary winding and the secondary winding are arranged individually adjacent to each other.

As a result, the winding directions of the windings belonging to the primary winding and the secondary winding are made different from each other, so that the received voltage on the secondary winding side can be raised while canceling the electromotive force due to the external magnetic flux interlinking the primary winding and the secondary winding. As a result, the signal transfer can be made to avoid a risk, as might otherwise invite a malfunction, while insulating the sending side and the receiving side electrically, and the power electronic device can be low priced and small in size.

In the transformer unit according to the third aspect of the invention, the primary winding includes a first winding and a second winding identical to each other in their winding directions such that the leading end of the first winding of the primary winding and the trailing end of the second winding of the primary winding are connected with each other, and such that the trailing end of the first winding of the primary winding and the leading end of the second winding of the primary winding are connected with each other; the secondary winding includes a first winding and a second winding identical to each other in their winding directions such that the leading end of the first winding of the secondary winding and the leading end of the second winding of the secondary winding are connected with each other, or such that the trailing end of the first winding of the secondary winding and the trailing end of the second winding of the secondary winding are connected with each other; and the individual first windings and the individual second windings are coaxially arranged whereas the first windings and the second windings of the primary winding and the secondary winding are arranged individually adjacent to each other. As a result, even in case the winding directions of the windings belonging to the primary winding and the secondary winding are made identical to each other, the received voltage on the secondary winding side can be raised by individually changing the method of connecting the windings belonging to the primary winding and the secondary winding, while canceling the electromotive force due to the external magnetic flux interlinking the primary winding and the secondary winding.

In the transformer unit according to the fourth aspect of the invention, the primary winding includes a first winding and a second winding different from each other in their winding directions such that the leading end of the first winding of the primary winding and the leading end of the second winding of the primary winding are connected with each other, and such that the trailing end of the first winding of the primary winding and the trailing end of the second winding of the primary winding are connected with each other; the secondary winding includes a first winding and a second winding identical to each other in their winding directions such that the leading end of the first winding of the secondary winding and the leading end of the second winding of the secondary winding are connected with each other, or such that the trailing end of the first winding of the secondary winding and the trailing end of the second winding of the secondary winding are connected with each other; and the individual first windings and the individual second windings are coaxially arranged whereas the first windings and the second windings of the primary winding and the secondary winding are arranged individually adjacent to each other.

As a result, even if the winding directions of the windings belonging to the primary winding are made different from each other whereas the winding directions of the winding belonging to the secondary winding are made identical to each other, the received voltage on the secondary winding side can be raised by individually changing the method of connecting the windings belonging to the primary winding and the secondary winding, while canceling the electromotive force due to the external magnetic flux interlinking the primary winding and the secondary winding.

In the transformer unit according to the fifth aspect of the invention, the primary winding includes a first winding and a second winding identical to each other in their winding directions such that the leading end of the first winding of the primary winding and the trailing end of the second winding of the primary winding are connected with each other, and such that the trailing end of the first winding of the primary winding and the leading end of the second winding of the primary winding are connected with each other; the secondary winding includes a first winding and a second winding different from each other in their winding directions such that the leading end of the first winding of the secondary winding and the trailing end of the second winding of the secondary winding are connected with each other, or such that the trailing end of the first winding of the secondary winding and the leading end of the second winding of the secondary winding are connected with each other; and the individual first windings and the individual second windings are coaxially arranged whereas the first windings and the second windings of the primary winding and the secondary winding are arranged individually adjacent to each other.

As a result, even if the winding directions of the windings belonging to the primary winding are made identical to each other whereas the winding directions of the winding belonging to the secondary winding are made different from each other, the received voltage on the secondary winding side can be raised by individually changing the method of connecting the windings belonging to the primary winding and the secondary winding, while canceling the electromotive force due to the external magnetic flux interlinking the primary winding and the secondary winding.

In the transformer unit according to the sixth aspect of the invention, the first windings and the second windings of the secondary winding are substantially identical in their numbers of turns. As a result, the external magnetic fluxes interlinking the first winding and the second winding of the secondary winding can be made substantially identical, so that the external magnetic flux interlinking the secondary winding can be substantially completely canceled.

In the transformer unit according to the seventh aspect of the invention, the air-core type insulated transformer is formed by a fine working technique. As a result, the primary winding and the secondary winding can have reduced winding diameters and reduced spacing. As a result, even if the external magnetic flux interlinks the primary winding and the secondary winding while enhancing the coupling coefficient of the same, the influence of noise can be reduced to improve the S/N ratio.

According to the eighth aspect of the invention, there is provided a power converting device comprising: a switching element for turning ON/OFF an electric current to flow into a load; a control circuit for generating a control signal to instruct the ON and OFF of the switching element; a drive circuit for driving the control terminal of the switching element on the basis of the control signal; and an air-core type insulated transformer including a sending-side primary winding and a receiving-side secondary winding so that the control circuit and the drive circuit may be insulated. In the power converting device, the sending-side primary winding includes a plurality of windings connected in parallel and set in their individual winding directions so that the directions of magnetic fields to be generated by exciting currents may be contrary to each other, and the receiving-side secondary winding includes a plurality of windings set in their individual winding directions so that electromotive forces to be generated by an external magnetic flux may cancel each other, and connected in series so as to raise the electromotive forces by a signal magnetic flux generated by the primary winding.

As a result, the secondary winding is equipped with the windings so that it can cancel the electromotive forces due to the external magnetic fluxes interlinking the secondary winding, thereby to reduce the superposition of the external magnetic fluxes as noise on the secondary winding, without using any magnetic core. As a result, the signal transfer can be made by avoiding the risk, as might otherwise invite the malfunction, while insulating the control circuit side and the switching element side electrically, and the power electronic device can be reduced in cost and size.

According to the invention, as has been described hereinbefore, while canceling the electromotive forces due to the external magnetic fluxes interlinking the secondary winding, the received voltage on the secondary winding side can be raised. Even in case the air-core insulated transformer is used as the signal transmitting insulated transformer, the superposition of the external magnetic fluxes as the noises on the secondary winding can be reduced to avoid the risk of inviting the malfunction and to provide a power electronic device of a low price and a small size.

### BRIEF DESCRIPTION OF THE DRAWINGS

The invention will be described with reference to the following drawings, where like numerals refer to like elements, wherein:

FIG. 1 is a block diagram of an intelligent power module for a step-up/step-down converter, to which a transformer unit according to one embodiment of the invention is applied;

FIG. 2 is an external view of the air-core type insulated transformer according to a first embodiment of the invention;

FIG. 3 is a diagram showing an interlinking state of an external magnetic flux of the air-core type insulated transformer of FIG. 2;

FIG. 4 is a diagram showing an interlinking state of a signal magnetic flux of the air-core type insulated transformer of FIG. 2;

FIG. 5 is an external view showing the air-core type insulated transformer of FIG. 2;

FIG. 6 is a diagram showing the dependency of transformer characteristics on the winding diameter;

FIG. 7 is a diagram of a transformer characteristic evaluating circuit;

FIG. 8 is a diagram showing dependency of coil characteristics on exciting coil current according to one embodiment of the invention;

FIG. 9 is a diagram showing dependency of coil characteristics on rate of change of exciting coil current according to one embodiment of the invention;

FIG. 10 is a diagram showing dependency of coil characteristics on received voltage according to one embodiment of the invention;

FIG. 11 is a diagram showing a circuit of a transformer unit according to a second embodiment of the invention;

FIG. 12 is a diagram showing a circuit of a transformer unit according to a third embodiment of the invention;

FIG. 13 is a diagram showing a circuit of a transformer unit according to a fourth embodiment of the invention;

FIG. 14 is a diagram showing a circuit of a transformer unit according to a fifth embodiment of the invention;

FIG. 15A presents sectional views of an insulated transformer according to a sixth embodiment of the invention, and FIG. 15B presents top plan views of the insulated transformer of FIG. 15A;

FIG. 16A-16L present sectional views showing an insulated transformer manufacturing method according to a seventh embodiment of the invention;

FIG. 17A-17H present sectional views showing the insulated transformer manufacturing method according to the seventh embodiment of the invention;

FIG. 18 is a sectional view showing the mounted state of an intelligent power module for a set-up/set-down converter according to an eighth embodiment of the invention;

FIG. 19 is a block diagram of a vehicle driving system using a step-up/step-down converter of the related art;

FIG. 20 is a block diagram of the step-up/step-down converter of FIG. 19;

FIG. 21 is a diagram showing a waveform of an electric current flowing through the reactor of FIG. 20 in the set-up operation;

FIG. 22 is a top plan view of a signal transmitting insulated transformer of the related art; and

FIG. 23 is a block diagram of a signal transmitting circuit using the signal transmitting insulated transformer of FIG. 22.

### DESCRIPTION OF THE PREFERRED EMBODIMENTS

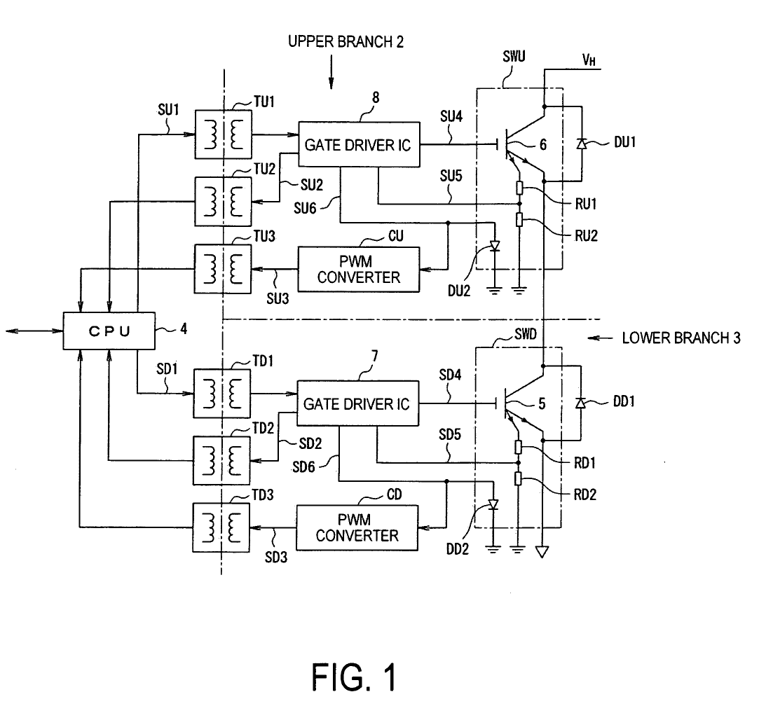

In the following, transformer units according to embodiments of the invention are described with reference to the accompanying drawings. FIG. 1 is a block diagram of an intelligent power module (IPM) for a step-up/step-down converter, to which a transformer unit according to one embodiment of the invention is applied. In FIG. 1, an intelligent power module for the step-up/step-down converter is equipped with switching elements SWU and SWD for turning ON/OFF an electric current to flow into loads, and a control circuit 1 for generating control signals to indicate the ON/OFF of the switching elements SWU and SWD. Here, the control circuit 1 can, for example, be constituted of a CPU 4 or a logic IC, or a system LSI having the logic IC and the CPU mounted thereon.

Further, the switching elements SWU and SWD are connected in series so that they act for an upper branch 2 and a lower branch 3, respectively. Further, the switching element SWU is equipped with an IGBT 6 for performing a switching action on the basis of a gate signal SU4. In parallel with the IGBT 6, there is connected a flywheel diode DU1 for feeding an electric current inversely of the electric current to flow through the IGBT 6. In addition, the chip having the IGBT 6 is equipped with a temperature sensor using the VF change of a diode DU2 due to the temperature change of the chip as its measurement principle, and a current sensor for detecting a main circuit current by shunting the emitter current of the IGBT 6 through resistors RU1 and RU2.

The switching element SWD is equipped with an IGBT 5 for performing a switching action on the basis of a gate signal SD4. In parallel with the IGBT 5, there is connected a flywheel diode DD1 for feeding an electric current inversely of the electric current to flow through the IGBT 5. Further, the chip having the IGBT 5 is equipped with a temperature sensor using the VF change of a diode DD2 due to the temperature change of the chip as its measurement principle, and a current sensor for detecting a main circuit current by shunting the emitter current of the IGBT 5 through resistors RD1 and RD2. The upper branch 2 is equipped with: a gate driver IC 8 having a protecting function to generate the gate signal SU4 for driving the control terminal of the IGBT 6, while monitoring an overheat detecting signal SU6 from the temperature sensor and an overcurrent detecting signal SU5 from the current sensor; and an analog PWM converter CU for generating a PWM signal corresponding to the temperature of the IGBT 6.

The lower branch 3 is equipped with: a gate driver IC 7 having a protecting function to generate the gate signal SD4 for driving the control terminal of the IGBT 5, while monitoring an overheat detecting signal SD6 from the temperature sensor and an overcurrent detecting signal SD5 from the current sensor; and an analog PWM converter CD for generating a PWM signal corresponding to the temperature of the IGBT 5. Between the side of the control circuit 1 to be earthed to the body casing, and the upper branch 2 and the lower branch 3 to take a high voltage, there are individually interposed air-core type insulated transformers TU1 to TU3 and TD1 to TD3, which are used in the control circuit 1 thereby to transfer the signals while electrically insulating the side of the upper branch 2 and the side of the lower branch 3.

On the side of the upper branch 2, specifically, a gate driver PWM signal SU1, as outputted from the CPU 4, is inputted through the air-core type insulated transformer TU1 to the gate driver IC 8 with the protecting function. An alarm signal SU2, as outputted from the gate driver IC 8 with the protecting function, is inputted to the CPU 4 through the air-core type insulated transformer TU2. An IGBT chip temperature PWM signal SU3, as outputted from the analog PWM converter CU, is inputted to the CPU 4 through the air-core type insulated transformer TU3.

On the side of the lower branch 3, a gate driver PWM signal SD1, as outputted from the CPU 4, is inputted through the air-core type insulated transformer TD1 to the gate driver IC 7 with the protecting function. An alarm signal SD2, as outputted from the gate driver IC 7 with the protecting function, is inputted to the CPU 4 through the air-core type insulated transformer TD2. An IGBT chip temperature PWM signal SD3, as outputted from the analog PWM converter CD, is inputted to the CPU 4 through the air-core type insulated transformer TD3.

Here, each of the air-core type insulated transformers TU1 to TU3 and TD1 to TD3 is equipped with a sending-side primary winding and a receiving-side secondary winding. Further, the primary winding of each of the air-core type insulated transformers TU1 to TU3 and TD1 to TD3 is equipped with at least a plurality of windings, which are so set in the winding directions that the directions of the magnetic fields generated by an exciting current may be contrary to each other, and which are connected in parallel. The secondary winding of each of the air-core type insulated transformers TU1 to TU3 and TD1 to TD3 is equipped with at least a plurality of windings, which are so set in the winding directions that the electromotive forces generated by the external magnetic flux may cancel each other, and which are so connected in series as to raise the electromotive forces by the signal magnetic fluxes generated by the primary winding of the air-core type insulated transformers TU1 to TU3 and TD1 to TD3.

The CPU 4 generates the gate driving PWM signals SD1 and SU1 for instructing the ON and OFF of the IGBTs 5 and 6, and insulates and transmits the gate driving PWM signals SD1 and SU1 to the gate driver ICs 7 and 8 with the protecting function, respectively, through the air-core type insulated transformers TD1 and TU1. On the basis of the gate driving PWM signals SD1 and SU1, further, the gate driver ICs 7 and 8 with the protecting function generate the gate signals SD4 and SU4, to drive the control terminals of the IGBTs 5 and 6 thereby to cause the IGBTs 5 and 6 to perform the switching actions.

The overheat detecting signals SD6 and SU6, as outputted from the temperature sensor, are inputted to the gate driver ICs 7 and 8 with the protecting function, respectively, and the overcurrent detecting signal SD5 and SU5, as outputted from the current sensor, are inputted to the gate driver ICs 7 and 8 with the protecting function, respectively. Further, the gate driver ICs 7 and 8 with the protecting function transmit, in case they exceed the threshold value, at which the IGBTs 5 and 6 are not broken, the alarm signals SD2 and SU2 to the CPU 4 through the air-core type insulated transformers TD2 and TU2, respectively. The CPU 4 stops, when it receives the alarm signals SD2 and SU2 from the gate driver ICs 7 and 8 with the protecting function, respectively, the generations of the gate driving PWM signals SD1 and SU1, thereby to shut the electric currents to flow through the IGBTs 5 and 6.

The gate driver ICs 7 and 8 with the protecting function release, if it is decided on the basis of the overheat detecting signals SD6 and SU6 outputted from the temperature sensor and the overcurrent detecting signal SD5 and SU5 outputted from the current sensor that the gate driver ICs 7 and 8 fall under the threshold value, at which the IGBTs 5 and 6 have not failed, the alarm signals SD2 and SU2 elapse after a constant time period. In the case of fine monitoring, the overheat detecting signals SD6 and SU6, as outputted from the temperature sensor, are inputted to the analog PWM converters CD and CU, respectively. The analog PWM converters CD and CU convert the analog values of the overheat detecting signals SD6 and SU6, respectively, into digital signals to generate the IGBT chip temperature PWM signals SD3 and SU3, respectively, and transmit the IGBT chip temperature PWM signals SD3 and SU3 to the CPU 4 through the air-core type insulated transformers TD3 and TU3, respectively. Further, the CPU 4 calculates the chip temperatures of the IGBTs 5 and 6 from the IGBT chip temperature PWM signals SD3 and SU3, respectively, so that it can lower the switching frequencies of the IGBTs 5 and 6 stepwise or can stop the switching, in accordance with the threshold values of predetermined several steps.

The primary windings and the secondary windings of the air-core type insulated transformers TU1 to TU3 and TD1 to TD3 are individually equipped with these windings so that they can cancel the external magnetic fluxes interlinking the primary winding and the secondary winding, thereby reducing the superposition of the external magnetic fluxes as noise on the primary winding and the secondary winding without using any magnetic core. Further, the windings belonging to the primary windings of the air-core type insulated transformers TU1 to TU3 and TD1 to TD3 are connected in parallel, and the windings belonging to the secondary windings on the receiving side are connected in series, the self-inductance of the secondary windings can be increased while the self-inductance of the primary windings is decreased, so that the received voltage on the secondary winding side can be augmented. As a result, the signal transfer can be made by avoiding a risk, as might otherwise invite a malfunction, while insulating the control circuit 1 electrically from the upper branch 2 and the lower branch 3, and the intelligent power module for the set-up/set-down converter can be reduced in cost and size.

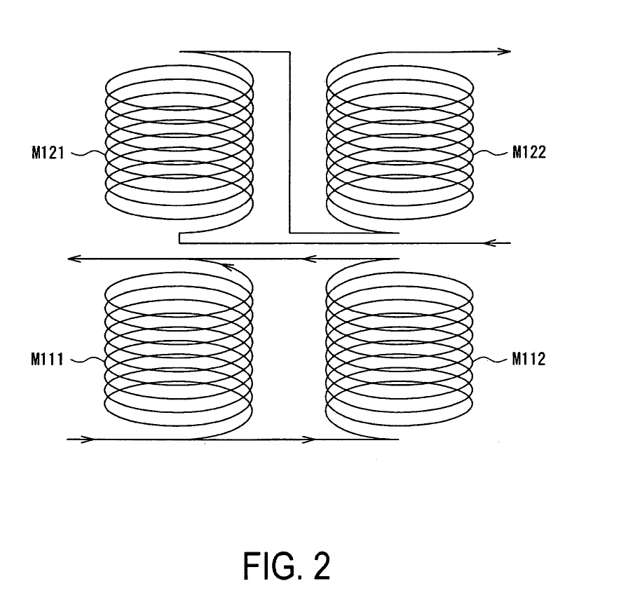

FIG. 2 is an external view of the air-core type insulated transformer according to a first embodiment of the invention. In FIG. 2, the air-core type insulated transformers TU1 to TU3 and TD1 to TD3 of FIG. 1 can be equipped with a first winding M111 and a second winding M112 of the primary winding for playing the role of the sending side and with a first winding M121 and a second winding M122 of the secondary winding for playing the role of the receiving side. Here, the first winding M111 and the second winding M112 of the primary winding can be so individually set in their winding directions that the directions of the magnetic fields generated by the exciting current may be contrary to each other, and can be connected in parallel. The first winding M121 and the second winding M122 of the secondary winding can be so individually set in their winding directions that the electromotive forces generated by the external magnetic fluxes may cancel each other, and can be so connected in series as to enhance the electromotive forces by the signal magnetic fluxes generated by the primary winding.

For example, the first winding M111 and the second winding M112 of the primary winding can be wound in different winding directions, and can be arranged close to each other. Further, the first winding M121 and the second winding M122 of the secondary winding can be wound in different winding directions, and can be arranged close to each other. Further, the first winding M111 of the primary winding and the first winding M121 of the secondary winding can be arranged coaxially with each other, and the second winding M112 of the primary winding and the second winding M122 of the secondary winding can also be arranged coaxially with each other. In addition, the leading end of the first winding M111 of the primary winding can be connected with the leading end of the second winding M112, and the trailing end of the first winding M111 of the primary winding can be connected with the trailing end of the second winding M112. Further, the trailing end of the first winding M121 of the secondary winding can be connected with the leading end of the second winding M122, or the leading end of the first winding M121 of the secondary winding can be connected with the trailing end of the second winding M122.

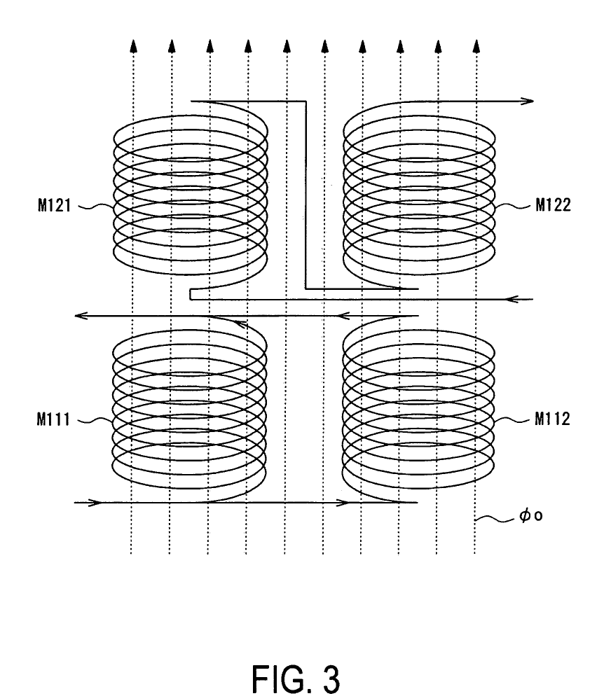

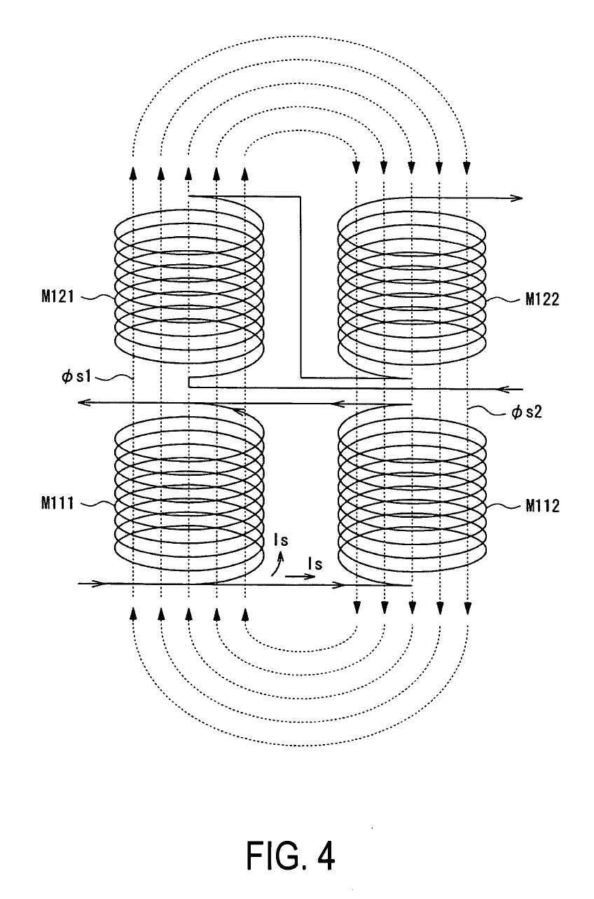

FIG. 3 is a diagram showing an interlinking state of an external magnetic flux of the air-core type insulated transformer of FIG. 2. In FIG. 3, an external magnetic flux φ0 intersects both the first winding M121 and the second winding M122 of the secondary winding substantially equivalently in the same direction. FIG. 4 is a diagram showing an interlinking state of the signal magnetic flux of the air-core type insulated transformer of FIG. 2. In FIG. 4, the signal magnetic flux φs1, which is generated by an exciting current Is having flown to the first winding M111 of the primary winding, is formed to turn on the axis of the first winding M111 of the primary winding, and interlinks mostly the first winding M121 of the secondary winding arranged on the same axis as that of the first winding M111 of the primary winding and partially the second winding M122 of the secondary winding.

The signal magnetic flux φs2, which is generated by an exciting current Is having flown to the second winding M112 of the primary winding, is formed to turn on the axis of the second winding M112 of the primary winding, and interlinks mostly the second winding M122 of the secondary winding arranged on the axis the same as that of the second winding M112 of the primary winding and partially the first winding M121 of the secondary winding. If the magnetic flux interlinking to the winding turned on is changed, the generated voltage of both ends of the winding can be represented by the following Faraday's Law.

$$∮ \vec{E} \cdot d \vec{I} = - {\int }_{S} \frac{\partial \vec{B}}{\partial t} \cdot d \vec{S} \qquad ( 2 )$$

It is understood from this Formula (2) that the factors to exert influences on the signs of the voltage to be generated by the magnetic flux change are the winding direction (dS) of the winding and the magnetic flux direction (B). Further, the electromotive forces by the external magnetic flux φ0 to be generated by the main circuit current have equivalent values of different signs, because the first winding M121 and the second winding M122 of the secondary winding are wound in different directions, so that they can cancel each other. This cancellation of those electromotive forces is the most effective in case the winding numbers of the first winding M121 and the second winding M122 of the secondary winding are substantially equal.

For a signal magnetic flux Js, the first winding M121 and the second winding M122 of the secondary winding generate the electromotive forces in the same direction, and these electromotive forces rise in their levels. By connecting the first winding M111 and the second winding M112 of the primary winding in parallel, and by connecting the first winding M121 and the second winding M122 of the secondary winding in series, further, the self inductance of the secondary winding can be increased while reducing the self inductance of the primary winding, so that the received voltage on the side of the secondary winding can be raised.

With the constitution thus far described, the electromotive force level by a signal magnetic flux φs can be raised while suppressing the electromotive force level by the external magnetic flux φ0 of the main circuit current, so that the S/N ratio of the signals can be raised even in case the air-core type insulated transformers TU1 to TU3 and TD1 to TD3 of FIG. 1 are used. Here, the windings shown in FIG. 2 are formed vertically, but may also be exemplified by a flat type coil formed by the fine working technique.

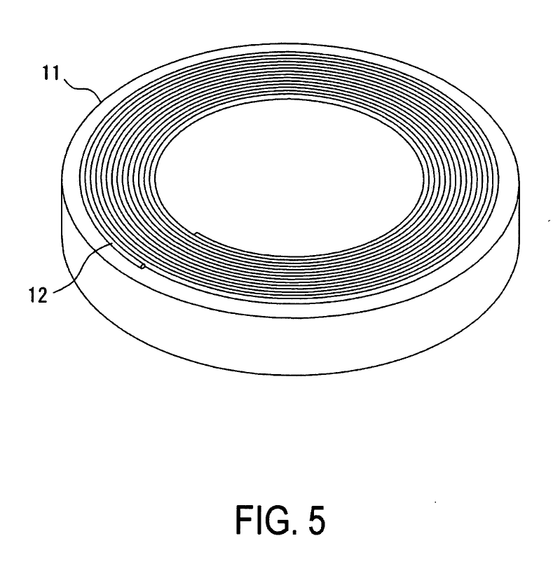

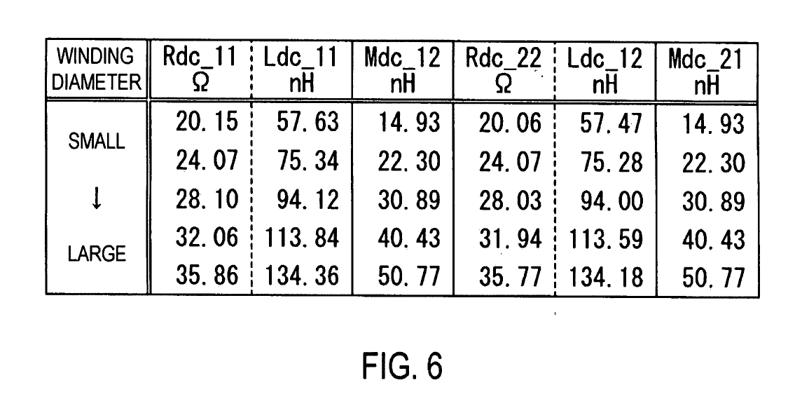

FIG. 5 is an external view showing the schematic constitution of the air-core type insulated transformer of FIG. 2. In FIG. 5, the air-core type insulated transformer can be constituted by forming the sending-side coil on one surface of an insulator 12 and by forming a receiving-side coil on the other surface of the insulator 12. FIG. 6 is a diagram showing the dependency of the winding diameter of a transformer constant. In FIG. 6, the DC resistance Rdc_11 of the primary winding, the self inductance Ldc_11 of the primary winding, the DC resistance Rdc_22 of the secondary winding, the self-inductance Ldc_12 of the secondary winding, and the mutual inductance Mdc_12 and Mdc_21 between the primary winding and the secondary winding of the air-core type insulated transformer of FIG. 5 becomes the higher, as the winding diameter becomes the larger.

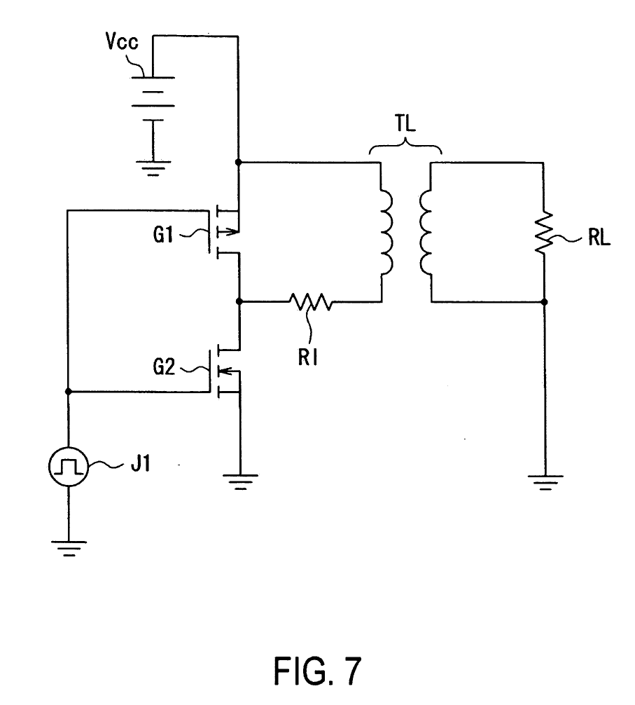

FIG. 7 is a diagram of a transformer characteristic evaluating circuit. In FIG. 7, field effect type transistors G1 and G2 are connected in series; the field effect type transistor G1 has its source connected with a power source Vcc; the field effect type transistor G2 has its source grounded to the earth; and the field effect transistors G1 and G2 have their gates connected with a signal source J1. Further, an air-core type insulated transformer TL has its primary winding connected at its one end with the power source Vcc and at its other end connected through a resistor R1 with the node between the field effect type transistors G1 and G2. Further, the air-core type insulated transformer TL has its secondary winding connected with a resistor RL.

In accordance with the level of the signal source J1, further, the field effect type transistors G1 and G2 can be alternately turned ON/OFF. When the field effect type transistor G1 is turned OFF whereas the field effect type transistor G2 is turned ON, the voltage of the power source Vcc is applied to the primary winding of the air-core type insulated transformer TL, and an electromotive force is generated in the secondary winding by the magnetic flux generated in the primary winding so that an electric current flows to the resistor RL. When the field effect type transistor G1 is turned ON whereas the field effect type transistor G2 is turned OFF, the primary winding of the air-core type insulated transformer TL is short-circuited through the resistor R1.

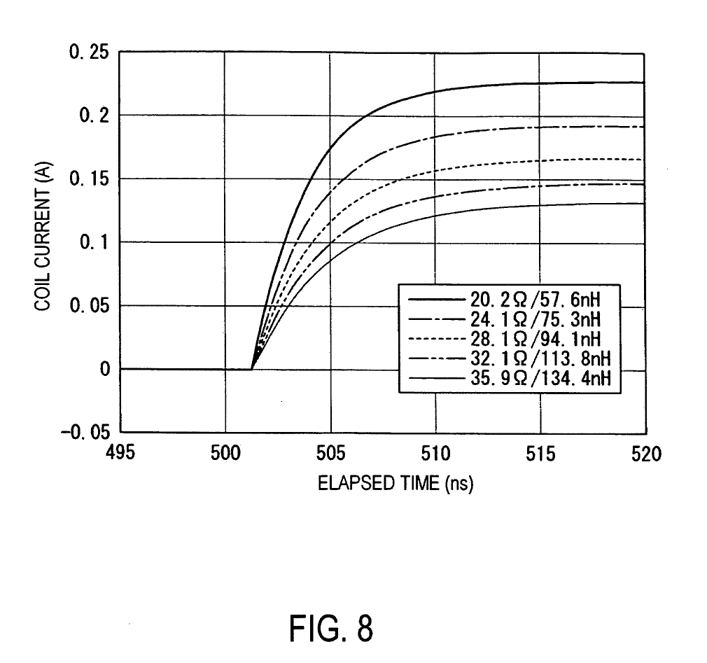

FIG. 8 is a diagram showing a coil constant dependency of an exciting coil current according to one embodiment of the invention. Here in the example of FIG. 8, the DC resistance Rdc_11 of the primary winding and the self-inductance Ldc_11 of the primary winding are changed by changing the winding diameter of the air-core type insulated transformer TL of FIG. 7, as shown in FIG. 6. The measurement is made on such an exciting coil current of the primary winding as flows at the changing time. From FIG. 8, it is found that the magnitude of the electric current to flow to the primary winding at a saturation time is inversely proportional to the DC resistance Rdc_11 of the primary winding, and that the rising inclination of the exciting coil current is inversely proportional to the self-inductance Ldc_11 of the primary winding.

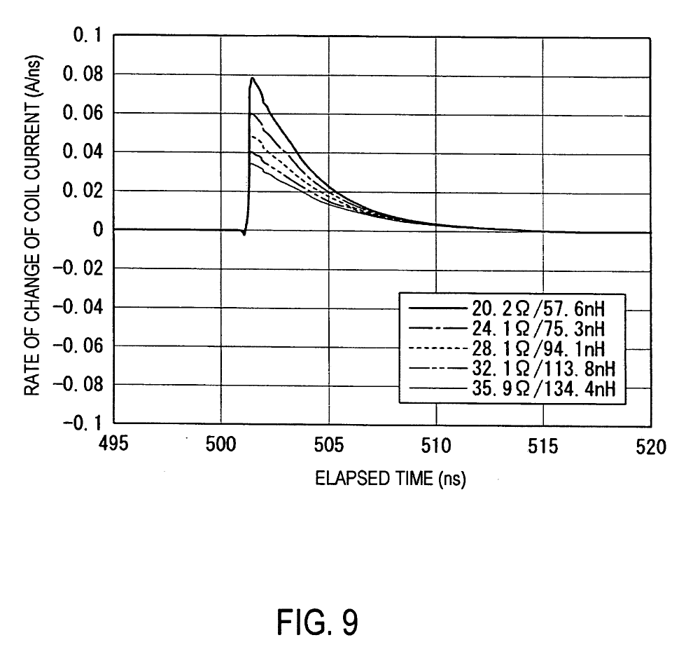

FIG. 9 is a diagram showing a coil constant dependency of an exciting coil current changing rate according to one embodiment of the invention. In the example of FIG. 9, the winding diameter of the air-core type insulated transformer TL of FIG. 7 is changed, as shown in FIG. 6, to change the DC resistance Rdc_11 of the primary winding and the self-inductance Ldc_11 of the primary winding thereby to decide the changing magnitude of the exciting coil current at that time. In FIG. 9, it is found that the peak value of the exciting coil current is inversely proportional to the self-inductance Ldc_11 of the primary winding.

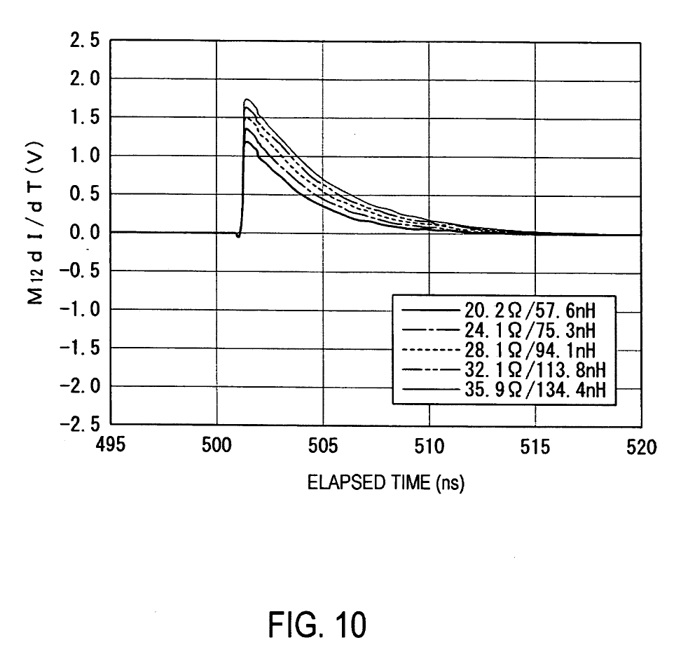

FIG. 10 is a diagram showing a coil constant dependency of a received voltage according to one embodiment of the invention. In the example of FIG. 10, the magnitude of the exciting coil current change at the time when the DC resistance Rdc_11 of the primary winding and the self-inductance Ldc_11 of the primary winding are changed by changing the winding diameter of the air-core type insulated transformer TL of FIG. 7, is multiplied by the mutual inductance Mdc_12 between the primary winding and the secondary winding, as shown in FIG. 6, thereby to determine the received voltage of the secondary winding of the air-core type insulated transformer TL. In FIG. 10, it is found that the received voltage of the secondary winding of the air-core type insulated transformer TL rises the higher as the winding diameter of the air-core type insulated transformer TL of FIG. 7 becomes the larger.

Here, the received voltage V_{REV} of the secondary winding of the air-core type insulated transformer TL can be expressed by the following Formula:

V_{REV}=M₁₂*dI/dT (3).

Here, M₁₂ designates the mutual inductance between the primary winding and the secondary winding of the air-core type insulated transformer TL, and dI/dT designates a time change of the exciting coil current.

From Formula (3), the received voltage V_{REV} of the secondary winding of the air-core type insulated transformer TL can be raised by enlarging either the mutual inductance M₁₂ between the primary winding and the secondary winding of the air-core type insulated transformer TL or the time change dI/dT of the exciting coil current. In FIG. 2, therefore, by connecting the first winding M111 and the second winding M112 of the primary winding in parallel, the self-inductance of the primary winding can be reduced to one half as high as the value of the single first winding M111 and the single second winding M112, thereby to increase the time change dI/dT of the exciting coil current. In FIG. 2, further, by connecting the first winding M121 and the second winding M122 of the secondary winding in series, the self-inductance of the secondary winding can be increased twice as high as that of the single first winding M121 and the single second winding M122, thereby to increase the mutual inductance between the primary winding and the secondary winding.

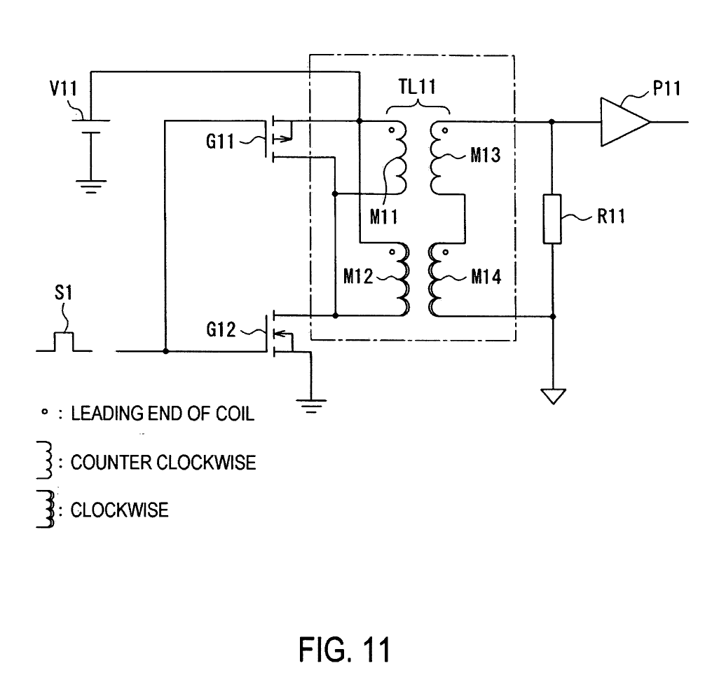

FIG. 11 is a diagram showing a circuit constitution of a transformer unit according to a second embodiment of the invention. In FIG. 11, field effect type transistors G11 and G12 are connected in series. The field effect type transistor G11 has its source connected with a power source V11, and the field effect type transistor G12 has its source grounded to the earth. An air-core type insulated transformer TL11 is equipped at its primary winding with a first winding M11 and a second winding M12 of different winding directions. The leading end of the first winding M11 of the primary winding and the leading end of the second winding M12 of the primary winding are connected with each other, and the trailing end of the first winding M11 of the primary winding and the trailing end of the second winding M12 of the primary winding are connected with each other. In the example of FIG. 11, the windings M11 and M13 are counter-clockwise, and the windings M12 and M14 are clockwise. The winding directions are indicated by changing the winding symbols, as shown (likewise in the following).

the air-core type insulated transformer TL11 is equipped at its secondary winding with the first winding M13 and the second winding M14 of different winding directions. The trailing end of the first winding M13 of the secondary winding and the leading end of the second winding M14 of the secondary winding are connected with each other. Here, unlike the method in which the trailing end of the first winding M13 and the leading end of the second winding M14 of the secondary winding of the air-core type insulated transformer TL11 are connected, the leading end of the first winding M13 and the trailing end of the second winding M14 of the secondary winding of the air-core type insulated transformer TL11 may also be connected with each other.

Here, it is preferred that the first winding M11 of the primary winding and the first winding M13 of the secondary winding of the air-core type insulated transformer TL11 are arranged coaxially with each other, that the second winding M12 of the primary winding and the second winding M14 of the secondary winding of the air-core type insulated transformer TL11 are arranged coaxially with each other, that the first winding M11 and the second winding M12 of the primary winding of the air-core type insulated transformer TL11 are arranged adjacent to each other, and that the first winding M13 and the second winding M14 of the secondary winding of the air-core type insulated transformer TL11 are arranged adjacent to each other.

Further, the leading ends of the first winding M11 of the primary winding and the second winding M12 of the primary winding of the air-core type insulated transformer TL11 are connected with the power source V11, and the trailing ends of the first winding M11 of the primary winding and the second winding M12 of the primary winding of the air-core type insulated transformer TL11 are connected with the node of the field effect type transistors G11 and G12. Further, a resistor R11 is connected between the leading end of the first winding M13 of the secondary winding and the trailing end of the second winding M14 of the secondary winding of the air-core type insulated transformer TL11, and an amplifier P11 is connected with the leading end of the first winding M13 of the secondary winding of the air-core type insulated transformer TL11.

In accordance with the level of a drive signal S1, further, the field effect type transistors G11 and G12 can be alternately turned ON/OFF. When the field effect type transistor G11 is turned OFF and when the field effect type transistor G12 is turned ON, further, the voltage of the power source V11 is applied in parallel to the first winding M11 of the primary winding and the second winding M12 of the primary winding of the air-core type insulated transformer TL11. By the magnetic flux generated between the first winding M11 of the primary winding and the second winding M12 of the primary winding, an electromotive force is generated at the first winding M13 of the secondary winding and the second winding M14 of the secondary winding so that an electric current flows to the resistor R11. Further, the voltage drop at the time when the electric current flows to the resistor R11 is amplified by the amplifier P11 so that it is outputted as the output signal.

When the field effect type transistor G11 is turned ON and when the field effect type transistor G12 is turned OFF, the first winding M11 of the primary winding and the second winding M12 of the primary winding of the air-core type insulated transformer TL11 are individually short-circuited. Thus, the winding directions of the first winding M11 of the primary winding and the second winding M12 of the primary winding of the air-core type insulated transformer TL11 are made different from each other, and the winding directions of the first winding M13 of the secondary winding and the second winding M14 of the secondary winding of the air-core type insulated transformer TL11 are made different from each other. As a result, the received voltage on the secondary winding side can be raised while canceling the electromotive forces due to the magnetic flux interlinking the primary winding and the secondary winding of the air-core type insulated transformer TL11.

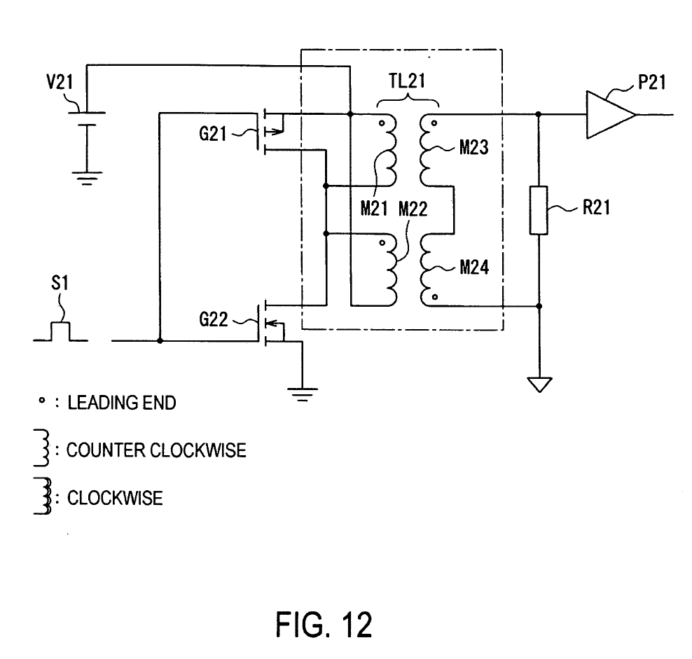

FIG. 12 is a diagram showing a circuit constitution of a transformer unit according to a third embodiment of the invention. In FIG. 12, field effect type transistors G21 and G22 are connected in series. The field effect type transistor G21 has its source connected with a power source V21, and the field effect type transistor G22 has its source grounded to the earth. Further, the air-core type insulated transformer TL21 is equipped at its primary winding with a first winding M21 and a second winding M22 of identical winding directions. The leading end of the first winding M21 of the primary winding and the trailing end of the second winding M22 of the primary winding are connected with each other, and the trailing end of the first winding M21 of the primary winding and the leading end of the second winding M22 of the primary winding are connected with each other.

the air-core type insulated transformer TL21 is equipped at its secondary winding with a first winding M23 and a second winding M24 of identical winding directions, and the trailing end of the first winding M23 of the secondary winding and the trailing end of the second winding M24 of the secondary winding are connected with each other. Here, unlike the method in which the trailing end of the first winding M23 of the secondary winding and the trailing end of the second winding M24 of the secondary winding of the air-core type insulated transformer TL21 are connected, the leading end of the first winding M23 of the secondary winding and the leading end of the second winding M24 of the secondary winding of the air-core type insulated transformer TL21 may also be connected with each other.

Here, it is preferred that the first winding M21 of the primary winding and the first winding M23 of the secondary winding of the air-core type insulated transformer TL21 are arranged coaxially with each other, that the second winding M22 of the primary winding and the second winding M24 of the secondary winding of the air-core type insulated transformer TL21 are arranged coaxially with each other, that the first winding M21 and the second winding M22 of the primary winding of the air-core type insulated transformer TL21 are arranged adjacent to each other, and that the first winding M23 and the second winding M24 of the secondary winding of the air-core type insulated transformer TL21 are arranged adjacent to each other.

Further, the leading end of the first winding M21 of the primary winding and the trailing end of the second winding M22 of the primary winding of the air-core type insulated transformer TL21 are connected with the power source V21, and the trailing end of the first winding M21 of the primary winding and the trailing end of the second winding M22 of the primary winding of the air-core type insulated transformer TL21 are connected with the node of the field effect type transistors G21 and G22. Further, a resistor R21 is connected between the leading end of the first winding M23 and the leading end of the second winding M24 of the secondary winding of the air-core type insulated transformer TL21, and an amplifier P21 is connected with the leading end of the first winding M23 of the secondary winding of the air-core type insulated transformer TL21.

In accordance with the level of a drive signal S1, further, the field effect type transistors G21 and G22 can be alternately turned ON/OFF. When the field effect type transistor G21 is turned OFF and when the field effect type transistor G22 is turned ON, further, the voltage of the power source V21 is applied in parallel to the first winding M21 of the primary winding and the second winding M22 of the primary winding of the air-core type insulated transformer TL21. By the magnetic flux generated between the first winding M21 and the second winding M22 of the primary winding, an electromotive force is generated at the first winding M23 of the secondary winding and the second winding M24 of the secondary winding so that an electric current flows to the resistor R21. Further, the voltage drop at the time when the electric current flows to the resistor R21 is amplified by the amplifier P21 so that it is outputted as the output signal.

When the field effect type transistor G21 is turned ON and when the field effect type transistor G22 is turned OFF, the first winding M21 of the primary winding and the second winding M22 of the primary winding of the air-core type insulated transformer TL21 are individually short-circuited. Thus, the winding directions of the first winding M21 of the primary winding and the second winding M22 of the primary winding of the air-core type insulated transformer TL21 are made identical to each other, and the winding directions of the first winding M23 of the secondary winding and the second winding M24 of the secondary winding of the air-core type insulated transformer TL21 are made identical to each other. As a result, the received voltage on the secondary winding side can be raised while canceling the electromotive forces due to the magnetic flux interlinking the primary winding and the secondary winding of the air-core type insulated transformer TL21.

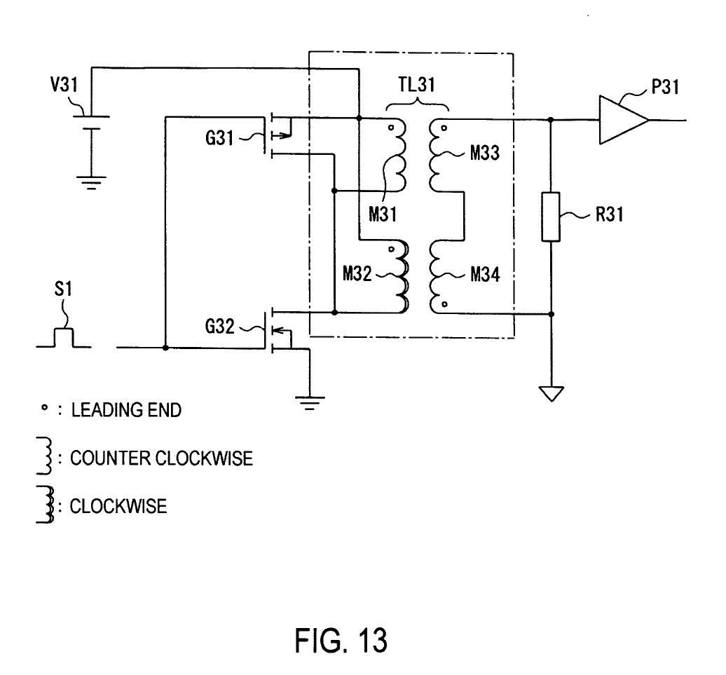

FIG. 13 is a diagram showing a circuit constitution of a transformer unit according to a fourth embodiment of the invention. In FIG. 13, field effect type transistors G31 and G32 are connected in series. The field effect type transistor G31 has its source connected with a power source V31, and the field effect type transistor G32 has its source grounded to the earth. Further, the air-core type insulated transformer TL31 is equipped at its primary winding with a first winding M31 and a second winding M32 of different winding directions. The leading end of the first winding M31 of the primary winding and the leading end of the second winding M32 of the primary winding are connected with each other, and the trailing end of the first winding M31 of the primary winding and the trailing end of the second winding M32 of the primary winding are connected with each other.

the air-core type insulated transformer TL31 is equipped at its secondary winding with a first winding M33 and a second winding M34 of different winding directions, and the trailing end of the first winding M33 of the secondary winding and the trailing end of the second winding M34 of the secondary winding are connected with each other. Here, unlike the method in which the trailing end of the first winding M33 of the secondary winding and the trailing end of the second winding M34 of the secondary winding of the air-core type insulated transformer TL31 are connected, the leading end of the first winding M33 of the secondary winding and the leading end of the second winding M34 of the secondary winding of the air-core type insulated transformer TL31 may also be connected with each other.

Here, it is preferred that the first winding M31 of the primary winding and the first winding M33 of the secondary winding of the air-core type insulated transformer TL31 are arranged coaxially with each other, that the second winding M32 of the primary winding and the second winding M34 of the secondary winding of the air-core type insulated transformer TL31 are arranged coaxially with each other, that the first winding M31 and the second winding M32 of the primary winding of the air-core type insulated transformer TL31 are arranged adjacent to each other, and that the first winding M33 and the second winding M34 of the secondary winding of the air-core type insulated transformer TL31 are arranged adjacent to each other.

Further, the leading ends of the first winding M31 of the primary winding and the second winding M32 of the primary winding of the air-core type insulated transformer TL31 are connected with the power source V31, and the trailing ends of the first winding M31 of the primary winding and the second winding M32 of the primary winding of the air-core type insulated transformer TL31 are connected with the node of the field effect type transistors G31 and G32. Further, a resistor R31 is connected between the leading end of the second winding M33 and the leading end of the second winding M34 of the secondary winding of the air-core type insulated transformer TL31, and an amplifier P31 is connected with the leading end of the first winding M33 of the secondary winding of the air-core type insulated transformer TL31.

In accordance with the level of a drive signal S1, further, the field effect type transistors G31 and G32 can be alternately turned ON/OFF. When the field effect type transistor G31 is turned OFF and when the field effect type transistor G32 is turned ON, further, the voltage of the power source V31 is applied in parallel to the first winding M31 of the primary winding and the second winding M32 of the primary winding of the air-core type insulated transformer TL31. By the magnetic flux generated between the first winding M31 of the primary winding and the second winding M32 of the primary winding, an electromotive force is generated at the first winding M33 of the secondary winding and the second winding M34 of the secondary winding so that an electric current flows to the resistor R31. Further, the voltage drop at the time when the electric current flows to the resistor R31 is amplified by the amplifier P31 so that it is outputted as the output signal.

When the field effect type transistor G31 is turned ON and when the field effect type transistor G32 is turned OFF, the first winding M31 of the primary winding and the second winding M32 of the primary winding of the air-core type insulated transformer TL31 are individually short-circuited. Thus, the winding directions of the first winding M31 of the primary winding and the second winding M32 of the primary winding of the air-core type insulated transformer TL31 are made different from each other, and the winding directions of the first winding M33 of the secondary winding and the second winding M34 of the secondary winding of the air-core type insulated transformer TL31 are made identical to each other. As a result, the received voltage on the secondary winding side can be raised while canceling the electromotive forces due to the magnetic flux interlinking the primary winding and the secondary winding of the air-core type insulated transformer TL31.

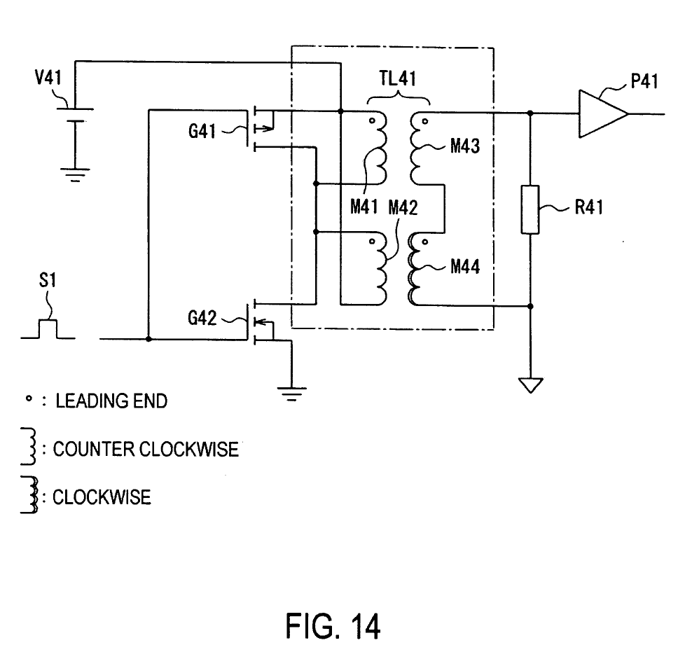

FIG. 14 is a diagram showing a circuit constitution of a transformer unit according to a fifth embodiment of the invention. In FIG. 14, field effect type transistors G41 and G42 are connected in series. The field effect type transistor G41 has its source connected with a power source V41, and the field effect type transistor G42 has its source grounded to the earth. Further, the air-core type insulated transformer TL41 is equipped at its primary winding with a first winding M41 and a second winding M42 of identical winding directions. The leading end of the first winding M41 of the primary winding and the trailing end of the second winding M42 of the primary winding are connected with each other, and the leading end of the first winding M41 of the primary winding and the trailing end of the second winding M42 of the primary winding are connected with each other.

the air-core type insulated transformer TL41 is equipped at its secondary winding with a first winding M43 and a second winding M44 of different winding directions, and the trailing end of the first winding M43 of the secondary winding and the leading end of the second winding M44 of the secondary winding are connected with each other. Here, unlike the method in which the trailing end of the first winding M43 of the secondary winding and the leading end of the second winding M44 of the secondary winding of the air-core type insulated transformer TL41 are connected, the leading end of the first winding M43 of the secondary winding and the trailing end of the second winding M44 of the secondary winding of the air-core type insulated transformer TL41 may also be connected with each other.

Here, it is preferred that the first winding M41 of the primary winding and the first winding M43 of the secondary winding of the air-core type insulated transformer TL41 are arranged coaxially with each other, that the second winding M42 of the primary winding and the second winding M44 of the secondary winding of the air-core type insulated transformer TL41 are arranged coaxially with each other, that the first winding M41 and the second winding M42 of the primary winding of the air-core type insulated transformer TL41 are arranged adjacent to each other, and that the first winding M43 and the second winding M44 of the secondary winding of the air-core type insulated transformer TL41 are arranged adjacent to each other.

Further, the leading end of the first winding M41 of the primary winding and the trailing end of the second winding M42 of the primary winding of the air-core type insulated transformer TL41 are connected with the power source V41, and the trailing end of the first winding M41 of the primary winding and the leading end of the second winding M42 of the primary winding of the air-core type insulated transformer TL41 are connected with the node of the field effect type transistors G41 and G42. Further, a resistor R41 is connected between the leading end of the second winding M43 and the trailing end of the second winding M44 of the secondary winding of the air-core type insulated transformer TL41, and an amplifier P41 is connected with the leading end of the first winding M43 of the secondary winding of the air-core type insulated transformer TL41.

In accordance with the level of a drive signal S1, further, the field effect type transistors G41 and G42 can be alternately turned ON/OFF. When the field effect type transistor G41 is turned OFF and when the field effect type transistor G42 is turned ON, further, the voltage of the power source V41 is applied in parallel to the first winding M41 of the primary winding and the second winding M42 of the primary winding of the air-core type insulated transformer TL41. By the magnetic flux generated between the first winding M41 of the primary winding and the second winding M42 of the primary winding, an electromotive force is generated at the first winding M43 of the secondary winding and the second winding M44 of the secondary winding so that an electric current flows to the resistor R41. Further, the voltage drop at the time when the electric current flows to the resistor R41 is amplified by the amplifier P41 so that it is outputted as the output signal.

When the field effect type transistor G41 is turned ON and when the field effect type transistor G42 is turned OFF, the first winding M41 of the primary winding and the second winding M42 of the primary winding of the air-core type insulated transformer TL41 are individually short-circuited. Thus, the winding directions of the first winding M41 of the primary winding and the second winding M42 of the primary winding of the air-core type insulated transformer TL41 are made identical to each other, and the winding directions of the first winding M43 of the secondary winding and the second winding M44 of the secondary winding of the air-core type insulated transformer TL41 are made different from each other. As a result, the received voltage on the secondary winding side can be raised while canceling the electromotive forces due to the magnetic flux interlinking the primary winding and the secondary winding of the air-core type insulated transformer TL41.

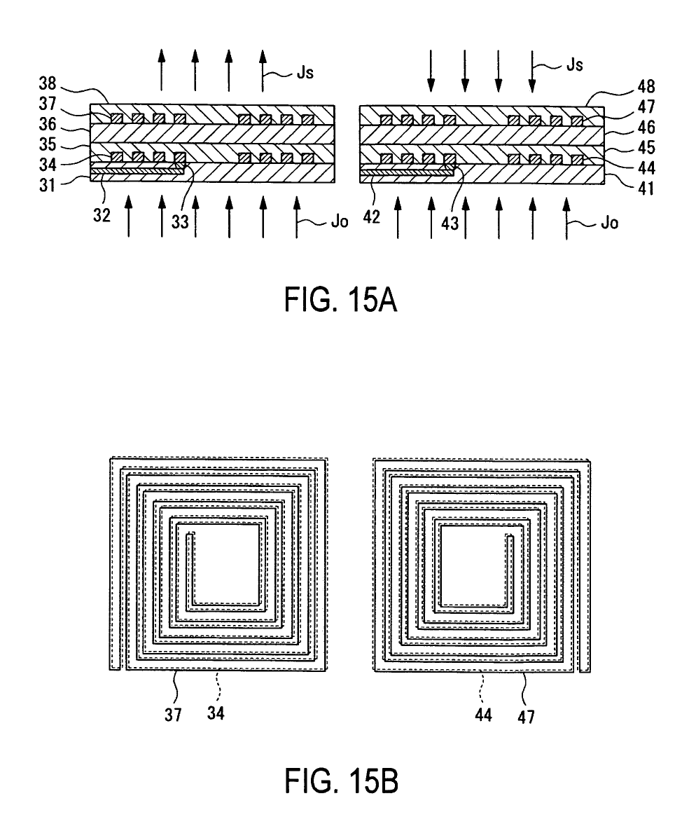

FIG. 15A presents sectional views of an insulated transformer according to a sixth embodiment of the invention, and FIG. 15B presents top plan views showing the schematic constitution of the insulated transformer of FIG. 15A. In FIG. 15A and FIG. 15B, an outgoing wiring layer 32 is buried in a substrate 31, and a first wiring 34 of the primary winding is formed over the substrate 31. Further, the first wiring 34 of the primary winding is connected with the outgoing wiring layer 32 through an outgoing portion 33. Over the first wiring 34 of the primary winding, there is formed a flattened film 35, over which a first winding 37 of the secondary winding is formed through an insulating layer 36. The first winding 37 of the secondary winding is covered with a protecting film 38.

an outgoing wiring layer 42 is buried in a substrate 41, over which a second winding 44 of the primary winding is formed. Further, the second winding 44 of the primary winding is connected with the outgoing wiring layer 42 through an outgoing portion 43. Over the second wiring 44 of the primary winding, there is formed a flattened film 45, over which a second winding 47 of the secondary winding is formed through an insulating layer 46. The second winding 47 of the secondary winding is covered with a protecting film 48.

Here, the first winding 34 of the primary winding and the first winding 37 of the secondary winding are set clockwise in their winding directions, and the second winding 44 of the primary winding and the second winding 47 of the secondary winding are set counter-clockwise in their winding directions. The first winding 34 of the primary winding and the second winding 44 of the primary winding can be arranged close to each other, and the first winding 37 of the secondary winding and the second winding 47 of the secondary winding can be arranged close to each other.

Further, the leading end of the first winding 34 of the primary winding can be connected with the leading end of the second winding 44 of the primary winding, and the trailing end of the first winding 34 of the primary winding can be connected with the trailing end of the second winding 44 of the primary winding. Further, the trailing end of the first winding 37 of the secondary winding can be connected with the leading end of the second winding 47 of the secondary winding, or the leading end of the first winding 37 of the secondary winding can be connected with the trailing end of the second winding 47 of the secondary winding.

In this case, the external magnetic flux φo intersects both the first winding 37 of the secondary winding and the second winding 47 of the secondary winding substantially equivalently in the identical directions. The signal magnetic flux φs, which is generated by the signal currents having flown through the first winding 34 of the primary winding and the second winding 44 of the primary winding, circulates on the axes of the first winding 34 of the primary winding and the second winding 44 of the primary winding, and mostly interlinks the first winding 37 of the secondary winding and the second winding 47 of the secondary winding, which are arranged on the identical axes of the first winding 34 of the primary winding and the second winding 44 of the primary winding. As a result, the electromotive voltage level by the signal magnetic flux φs can be raised to suppress the electromotive level by the external magnetic flux φo of the main circuit current, thereby to enhance the S/N ratio of the signal.

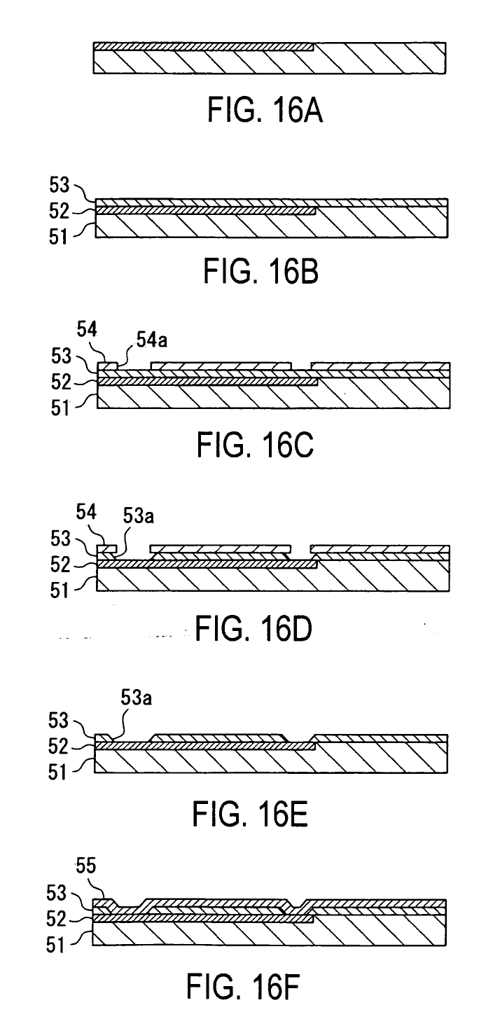

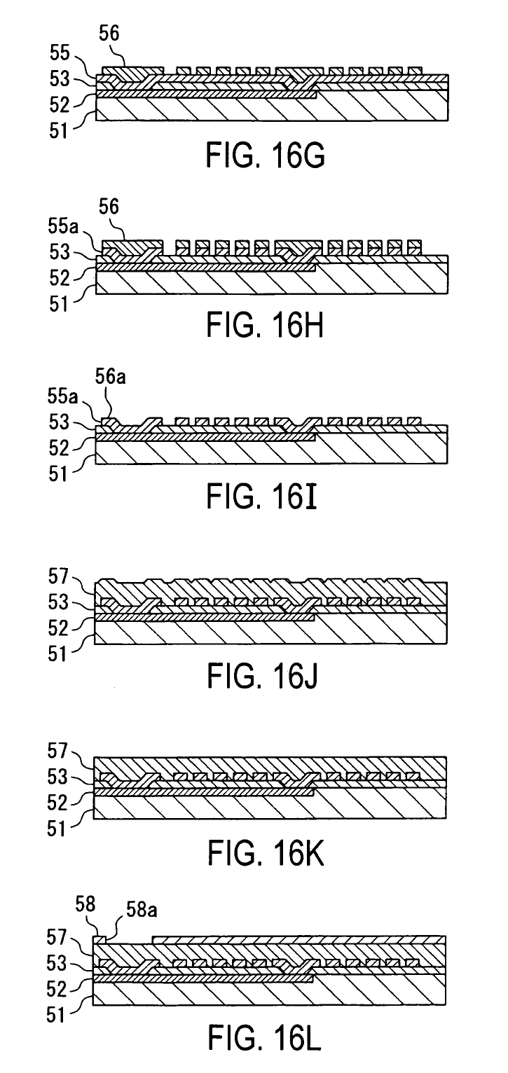

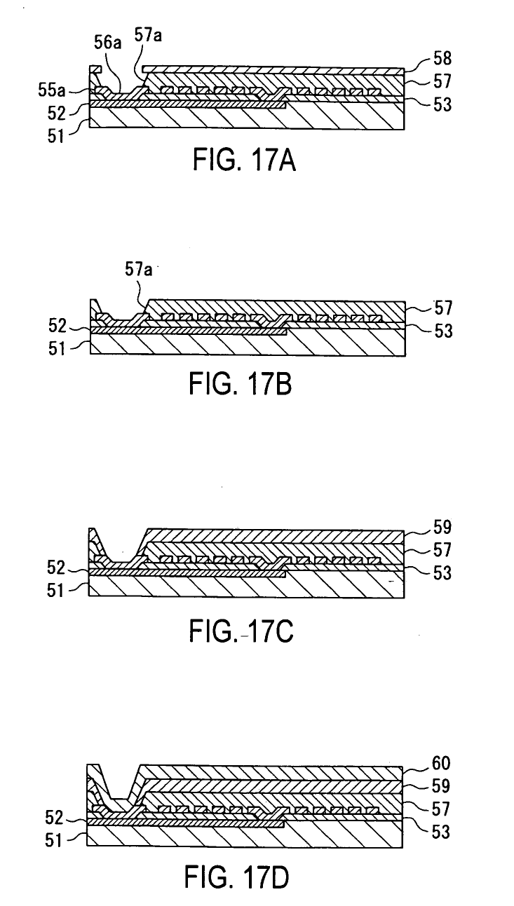

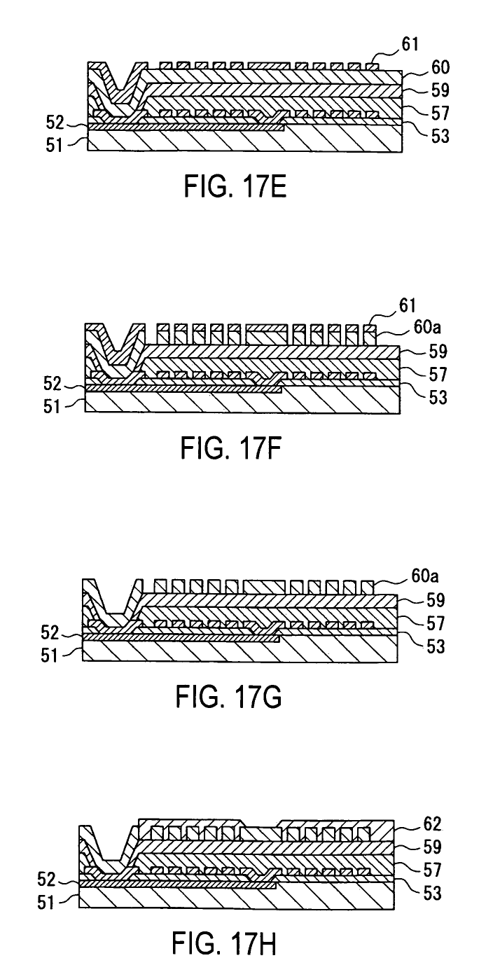

FIG. 16A-16L and FIG. 17A-17H present sectional views showing methods for manufacturing an insulated transformer according to a seventh embodiment of the invention. In FIG. 16A, an impurity such as As, P or B is selectively injected into the semiconductor substrate 51, thereby to form such an outgoing diffusion layer 52 in the semiconductor substrate 51 as is led out from the center of the primary coil pattern 55a. Here, the material for the semiconductor substrate 51 can be selected from Si, Ge, SiGe, SiC, SiSn, PbS, GaAs, InP, GaP, GaN or ZnSe.

Next, as shown in FIG. 16B, the insulating layer 53 is formed by the plasma CVD method or the like on the semiconductor substrate 51 having the outgoing diffusion layer 52 formed therein. Here, the material for the insulating layer 53 can be exemplified by a silicon oxide film or a silicon nitride film. Next, as shown in FIG. 16C, by using the photolithography technique, a resist pattern 54, which has an opening 54a formed to correspond to the outgoing portion from the center of the primary coil pattern 55a, is formed over the insulating layer 53. Next, as shown in FIG. 16D, the insulating layer 53 is etched by using the resist pattern 54 having the opening 54a as the mask, thereby to form such an opening 53a in the insulating layer 53 as to correspond to the outgoing portion from the center of the primary coil pattern 55a.

Next, as shown in FIG. 16E, the resist pattern 54 is peeled off from the insulating layer 53 by means of chemicals. Next, as shown in FIG. 16F, a conductive film 55 is formed over the insulating layer 53 by a sputtering or vapor deposition method. Here, the material for the conductive film 55 can be exemplified by a metal such as Al or Cu. Next, as shown in FIG. 16G, a resist pattern 56 corresponding to the primary coil pattern 55a is formed by using the photolithography technique.

Next, as shown in FIG. 16H, the primary coil pattern 55a is formed over the insulating layer 53 by etching the conductive film 55, using the resist pattern 56 as a mask. Next, as shown in FIG. 16I, the resist pattern 56 is peeled off from the primary coil pattern 55a by means of chemicals. Next, as shown in FIG. 16J, a flattened film 57 is formed by the plasma CVD method or the like over the insulating layer 53 having the primary coil pattern 55a. Here, the material for the flattened film 57 can be exemplified by the silicon oxide film or the silicon nitride film.

Next, as shown in FIG. 16K, the flattened film 57 is flattened and cleared of its surface roughness by an oblique etching method or CMP (Chemical Mechanical Polishing) method. Next, as shown in FIG. 16L, by using the photolithography technique, a resist pattern 58, which has an opening 58a formed to correspond to the wiring outgoing portion of the outer end of the secondary coil pattern 60a, is formed over the flattened film 57.

Next, as shown in FIG. 17A, the flattened film 57 is etched by using the resist pattern 58 having the opening 58a as a mask, to form an opening 57a corresponding to the wiring outgoing portion of the outer end of the primary coil pattern 55a. Next, as shown in FIG. 17B, the resist pattern 58 is peeled off from the flattened film 57 by means of chemicals. Next, as shown in FIG. 17C, a separating layer 59 for the primary coil pattern 55a and the secondary coil pattern 60a is formed over the flattened film 57. Here, the method for forming, the separating layer 59 can be exemplified by the method of applying a polyimide layer to the flattened film 57.

Next, as shown in FIG. 17D, a conductive film 60 is formed over the separating layer 59 by the sputtering or vapor deposition method. Here, the material for the conductive film 60 can be exemplified by a metal such as Al or Cu. Next, as shown in FIG. 17E, a resist pattern 61 corresponding to the secondary coil pattern 60a is formed by using the photolithography technique. Next, as shown in FIG. 17F, the conductive film 60 is etched by using the resist pattern 61 as a mask, thereby to form the secondary coil pattern 60a over the separating layer 59. Next, as shown in FIG. 17G, the resist pattern 61 is peeled off from the secondary coil pattern 60a by means of chemicals.

Next, as shown in FIG. 17H, a protecting film 62 is formed over the separating layer 59 having the secondary coil pattern 60a, by the plasma CVD method. Here, the material for the protecting film 62 can be exemplified by a silicon oxide film or a silicon nitride film. Further, the protecting film 62 is patterned by using the photolithography technique and the etching technique, to expose the end portions and the central portions of the secondary coil pattern 60a to the outside. As a result, the secondary coil pattern 60a can be laminated on the primary coil pattern 55a by the fine working technique, thereby to reduce the winding diameters of the primary coil pattern 55a and the secondary coil pattern 60a and to reduce the distance between the primary coil pattern 55a and the secondary coil pattern 60a.

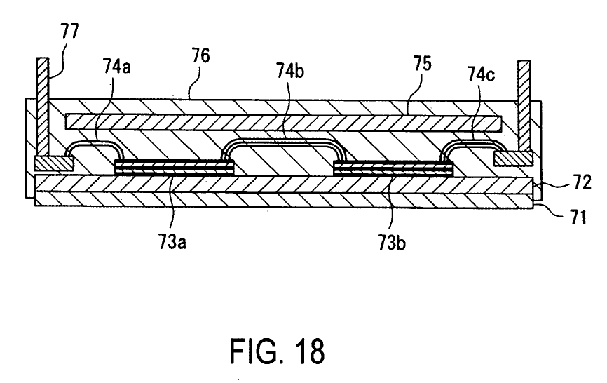

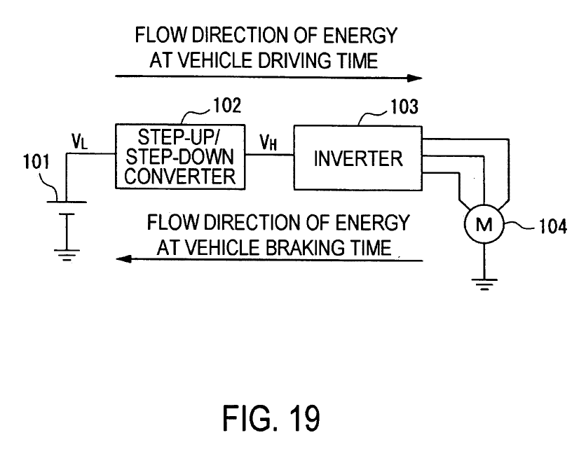

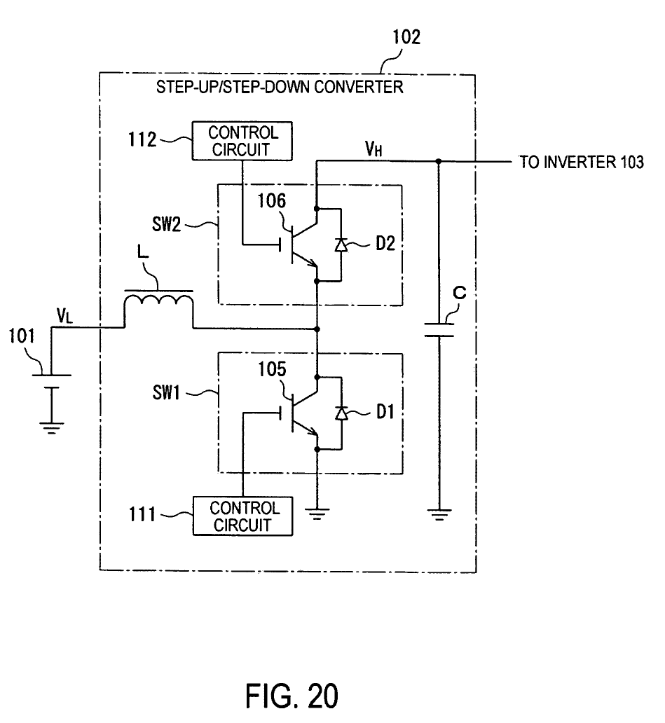

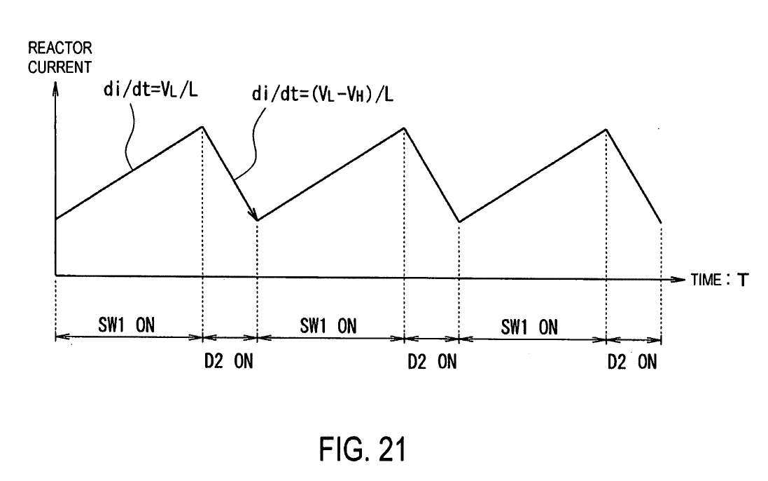

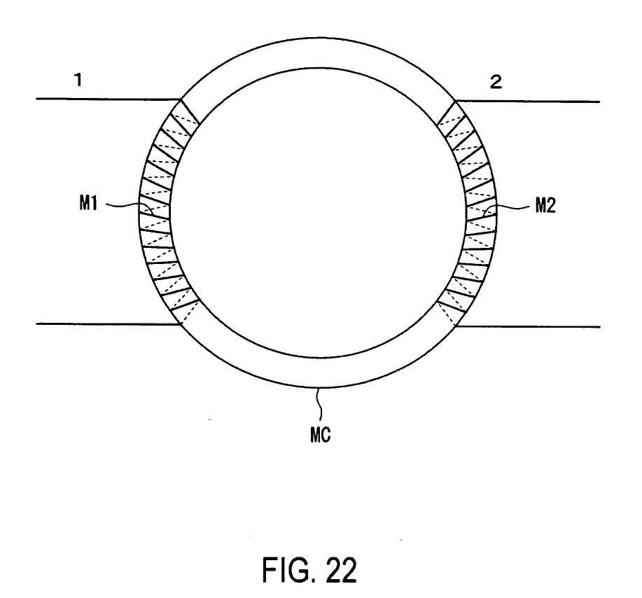

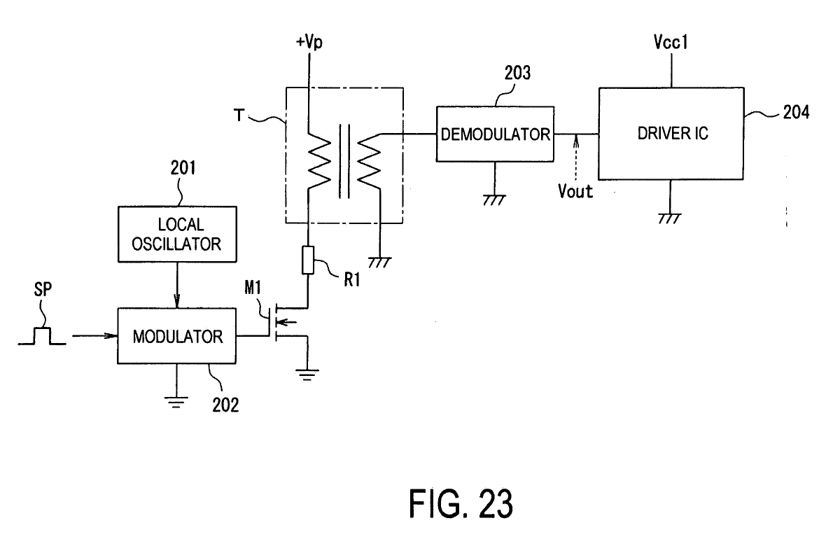

FIG. 18 is a sectional view showing the mounted state of an intelligent power module for a set-up/set-down converter according to an eighth embodiment of the invention. In FIG. 18, on a copper base 71 playing a heat radiation role, there are mounted an IGBT chip 73a and an FWD chip 73b through an insulating ceramic substrate 72. Further, the IGBT chip 73a and the FWD chip 73b are connected with each other through bonding wires 74a to 74c and further with a main terminal 77 for the outgoing of a main circuit current. Over the IGBT chip 73a and the FWD chip 73b, further, there is arranged a circuit substrate 75 for driving and monitoring the gate drive of the IGBT. The IGBT chip 73a, the FWD chip 73b and the circuit substrate 75 are sealed with a mold resin 76. Here, the IGBT chip 73a and the FWD chip 73b can constitute a switching element for conducting and blocking the electric current to flow into a load, and this switching element can be connected in series so that it can act for an upper branch and a lower branch. Further, the circuit substrate 75 can be equipped with a control circuit for generating a control signal to instruct the ON and OFF of the switching element.

Further, the main circuit current flows not only to the main terminal 77 but also to the bonding wires 74a to 74c for connecting the main terminal 77 with the IGBT chip 73a and the FWD chip 73b. However, the bonding wires 74a to 74c are arranged close to the circuit substrate 75, so that the magnetic field to be generated by the main circuit current flowing through the bonding wires 74a to 74c exerts a higher influence. This main circuit current is about 250 A at the highest in an ordinary running time, but may exceed 900 A under a load after an idle running.

Here, the air-core type insulated transformer is interposed between the control circuit side grounded to the vehicle body casing and the upper and lower branch sides to become a higher voltage. In the control circuit, the signals are transferred while the upper branch side and the lower branch side being electrically insulated by using the air-core type insulated transformer. Further, a plurality of windings are provided for the primary winding and the secondary winding of the air-core type insulated transformer such that the windings of the primary winding on the sending side of the air-core type insulated transformer are connected in parallel, whereas the windings of the secondary winding on the receiving side are connected in series. As a result, the self-inductance of the secondary winding can be increased while the self-inductance of the primary winding being decreased, so that the received voltage on the secondary winding side can be raised.

As a result, even in case a high current of the main circuit flows to the bonding wires 74a to 74c connecting the IGBT chip 73a, the FWD chip 73b and the main terminal 77 electrically, the signal level at the output voltage of the secondary winding on the receiving side of the air-core type insulated transformer can be made sufficiently high against the noise level of the main circuit current, so that a signal transmission having no malfunction can be performed even in the case of using the air-core type insulated transformer.

Here, the description of the foregoing modes of embodiment has been made on the method of equipping the primary winding of the air-core type insulated transformer with two windings and the secondary winding of the air-core type insulated transformer with the two windings. It is, however, arbitrary to equip the primary winding of the air-core type insulated transformer with three or more windings and to equip the secondary winding of the air-core type insulated transformer with three or more windings. It is also arbitrary that the windings of the primary winding and the secondary winding of the air-core type insulated transformer are different in number from each other.

It will of course be appreciated that the invention may be practiced otherwise than as specifically disclosed herein without departing from the scope of the invention.

What is claimed is:

1. A transformer unit comprising a primary winding on a sending side, and a secondary winding on a receiving side,
said primary winding including at least a plurality of windings connected in parallel and wound in respective individual winding directions so that respective directions of respective magnetic fields to be generated by respective exciting currents are contrary to each other, and
said secondary winding including at least a plurality of windings wound in respective winding directions so that respective electromotive forces to be generated by an external magnetic flux cancel each other, and connected in series so as to increase signal electromotive forces generated by said magnetic fields in said primary winding.

2. The transformer unit according to claim 1,
said primary winding including a first winding and a second winding different from each other in their winding directions such that a leading end of the first winding of said primary winding and a leading end of the second winding of said primary winding are connected with each other, and such that a trailing end of the first winding of said primary winding and a trailing end of the second winding of said primary winding are connected with each other, and
said secondary winding including a first winding and a second winding different from each other in their winding directions such that a leading end of the first winding of said secondary winding and a trailing end of the second winding of said secondary winding are connected with each other, or such that a trailing end of the first winding of said secondary winding and a leading end of the second winding of said secondary winding are connected with each other,
wherein the first winding of said primary winding is coaxial with the first winding of said secondary winding, and the second winding of said primary winding is coaxial with the second winding of said secondary winding, whereas the first and second windings of said primary winding are adjacent to each other, and the first and second windings of said secondary winding are adjacent to each other.

3. The transformer unit according to claim 1,
said primary winding including a first winding and a second winding identical to each other in their winding directions such that a leading end of the first winding of said primary winding and a trailing end of the second winding of said primary winding are connected with each other, and such that a trailing end of the first winding of said primary winding and a leading end of the second winding of said primary winding are connected with each other, and
said secondary winding including a first winding and a second winding identical to each other in their winding directions such that a leading end of the first winding of said secondary winding and a leading end of the second winding of said secondary winding are connected with each other, or such that a trailing end of the first winding of said secondary winding and a trailing end of the second winding of said secondary winding are connected with each other,
wherein the first winding of said primary winding is coaxial with the first winding of said secondary winding, and the second winding of said primary winding is coaxial with the second winding of said secondary winding, whereas the first and second windings of said primary winding are adjacent to each other, and the first and second windings of said secondary winding are adjacent to each other.

4. The transformer unit according to claim 1,
said primary winding including a first winding and a second winding different from each other in their winding directions such that the leading end of the first winding of said primary winding and the leading end of the second winding of said primary winding are connected with each other, and such that the trailing end of the first winding of said primary winding and the trailing end of the second winding of said primary winding are connected with each other, and
said secondary winding including a first winding and a second winding identical to each other in their winding directions such that a leading end of the first winding of said secondary winding and a leading end of the second winding of said secondary winding are connected with each other, or such that a trailing end of the first winding of said secondary winding and a trailing end of the second winding of said secondary winding are connected with each other,
wherein the first winding of said primary winding is coaxial with the first winding of said secondary winding, and the second winding of said primary winding is coaxial with the second winding of said secondary winding, whereas the first and second windings of said primary winding are adjacent to each other, and the first and second windings of said secondary winding are adjacent to each other.

5. The transformer unit according to claim 1,
said primary winding including a first winding and a second winding identical to each other in their winding directions such that a leading end of the first winding of said primary winding and a trailing end of the second winding of said primary winding are connected with each other, and such that a trailing end of the first winding of said primary winding and a leading end of the second winding of said primary winding are connected with each other, and
said secondary winding including a first winding and a second winding different from each other in their winding directions such that the leading end of the first winding of said secondary winding and the trailing end of the second winding of said secondary winding are connected with each other, or such that the trailing end of the first winding of said secondary winding and the leading end of the second winding of said secondary winding are connected with each other,
wherein the first winding of said primary winding is coaxial with the first winding of said secondary winding, and the second winding of said primary winding is coaxial with the second winding of said secondary winding, whereas the first and second windings of said primary winding are adjacent to each other, and the first and second windings of said secondary winding are adjacent to each other.

6. The transformer unit according to claim 1, wherein the first windings and the second windings of said secondary winding are substantially identical in their respective number of turns.

7. The transformer unit according to claim 1, wherein said air-core type insulated transformer is formed by a fine working technique.

8. A power converting device comprising:
a switching element configured to turn an electric current flowing into a load ON/OFF;
a control circuit configured to generate a control signal to instruct turning ON and OFF of said switching element;
a drive circuit configured to drive the control terminal of said switching element on the basis of said control signal; and
an air-core type insulated transformer including a sending-side primary winding and a receiving-side secondary winding positioned so that said control circuit and said drive circuit are insulated from each other,
wherein said sending-side primary winding includes at least a plurality of windings connected in parallel and wound in respective individual winding directions so that the directions of respective magnetic fields to be generated by respective exciting currents are contrary to each other, and
wherein said receiving-side secondary winding includes at least a plurality of windings wound in respective individual winding directions so that respective electromotive forces to be generated by an external magnetic flux cancel each other, and connected in series so as to raise the electromotive forces by a signal magnetic flux generated by said primary winding.

9. The power converting device according to claim 8,
said primary winding including a first winding and a second winding different from each other in their winding directions such that a leading end of the first winding of said primary winding and a leading end of the second winding of said primary winding are connected with each other, and such that a trailing end of the first winding of said primary winding and a trailing end of the second winding of said primary winding are connected with each other, and
said secondary winding including a first winding and a second winding different from each other in their winding directions such that a leading end of the first winding of said secondary winding and a trailing end of the second winding of said secondary winding are connected with each other, or such that a trailing end of the first winding of said secondary winding and a leading end of the second winding of said secondary winding are connected with each other,
wherein the first winding of said primary winding is coaxial with the first winding of said secondary winding, and the second winding of said primary winding is coaxial with the second winding of said secondary winding, whereas the first and second windings of said primary winding are adjacent to each other, and the first and second windings of said secondary winding are adjacent to each other.

10. The power converting device according to claim 8,
said primary winding including a first winding and a second winding identical to each other in their winding directions such that a leading end of the first winding of said primary winding and a trailing end of the second winding of said primary winding are connected with each other, and such that a trailing end of the first winding of said primary winding and a leading end of the second winding of said primary winding are connected with each other, and
said secondary winding including a first winding and a second winding identical to each other in their winding directions such that a leading end of the first winding of said secondary winding and a leading end of the second winding of said secondary winding are connected with each other, or such that a trailing end of the first winding of said secondary winding and a trailing end of the second winding of said secondary winding are connected with each other,
wherein the first winding of said primary winding is coaxial with the first winding of said secondary winding, and the second winding of said primary winding is coaxial with the second winding of said secondary winding, whereas the first and second windings of said primary winding are adjacent to each other, and the first and second windings of said secondary winding are adjacent to each other.

11. The power converting device according to claim 8,
said primary winding including a first winding and a second winding different from each other in their winding directions such that the leading end of the first winding of said primary winding and the leading end of the second winding of said primary winding are connected with each other, and such that the trailing end of the first winding of said primary winding and the trailing end of the second winding of said primary winding are connected with each other, and
said secondary winding including a first winding and a second winding identical to each other in their winding directions such that a leading end of the first winding of said secondary winding and a leading end of the second winding of said secondary winding are connected with each other, or such that a trailing end of the first winding of said secondary winding and a trailing end of the second winding of said secondary winding are connected with each other,
wherein the first winding of said primary winding is coaxial with the first winding of said secondary winding, and the second winding of said primary winding is coaxial with the second winding of said secondary winding, whereas the first and second windings of said primary winding are adjacent to each other, and the first and second windings of said secondary winding are adjacent to each other.

12. The power converting device according to claim 8,
said primary winding including a first winding and a second winding identical to each other in their winding directions such that a leading end of the first winding of said primary winding and a trailing end of the second winding of said primary winding are connected with each other, and such that a trailing end of the first winding of said primary winding and a leading end of the second winding of said primary winding are connected with each other, and
said secondary winding including a first winding and a second winding different from each other in their winding directions such that the leading end of the first winding of said secondary winding and the trailing end of the second winding of said secondary winding are connected with each other, or such that the trailing end of the first winding of said secondary winding and the leading end of the second winding of said secondary winding are connected with each other,
wherein the first winding of said primary winding is coaxial with the first winding of said secondary winding, and the second winding of said primary winding is coaxial with the second winding of said secondary winding, whereas the first and second windings of said primary winding are adjacent to each other, and the first and second windings of said secondary winding are adjacent to each other.

13. The power converting device according to claim 8, wherein the first windings and the second windings of said secondary winding are substantially identical in their respective number of turns.

14. The power converting device according to claim 8, wherein said air-core type insulated transformer is formed by a fine working technique.
